(19) United States
(12) Patent Application Publication
(10) Pub. No.: US 2026/0255814 A1
(43) Pub. Date: Aug. 27, 2026

(54) Display Substrate and Display Apparatus

(71) Applicants: Hefei BOE Joint Technology Co.,Ltd., Hefei, Anhui (CN); BOE Technology Group Co., Ltd., Beijing (CN); Beijing BOE Technology Development Co., Ltd., Beijing (CN)

(72) Inventors: Zhidong YUAN, Beijing (CN); Ying HAN, Beijing (CN); Xiuting LIU, Beijing (CN); Pan XU, Beijing (CN); Yongqian LI, Beijing (CN); Miao LIU, Beijing (CN)

(21) Appl. No.: 18/861,611

(22) PCT Filed: Sep. 7, 2023
(86) PCT No.: PCT/CN2023/117551

§ 371 Date: Oct. 30, 2024

(51) Int. Cl. H10K 59/131; G09G 3/3233; G09G 3/3266

(52) U.S. Cl. CPC H10K 59/131; G09G 3/3233; G09G 3/3266; G09G 2300/0452; G09G 2300/0819; G09G 2300/0842; G09G 2300/0861; G09G 2310/0286; G09G 2310/08; G09G 2330/021

(57) ABSTRACT

A display substrate has a display region and a non-display region provided on and surrounding at least one side of the display region the display region is provided with pixel drive circuits arranged in an array, and the non-display region is provided with a gate drive circuit and a gating signal line group, the gating signal line group includes: a plurality of gating signal lines, the gate drive circuit is electrically connected with the pixel drive circuits and the gating signal line group respectively; a gating signal line extends along a first direction the plurality of gating signal lines are arranged along a second direction, the gate drive circuit includes a plurality of shift registers, a shift registers includes a gating sub-circuit electrically connected with a portion of the gating signal lines in the gating signal line group.

### CROSS-REFERENCE TO RELATED APPLICATION

This application is a national stage application of PCT Application No. PCT/CN2023/117551, which is filed on Sep. 7, 2023 and entitled “Display Substrate and Display Apparatus”, the content of which should be regarded as being incorporated herein by reference.

### TECHNICAL FIELD

The present disclosure relates to, but is not limited to, the field of display technologies, and more particularly, to a display substrate and a display apparatus.

### BACKGROUND

An Organic Light Emitting Diode (OLED for short) and a Quantum dot Light Emitting Diode (QLED for short) are active light emitting display devices and have advantages such as self-luminescence, wide viewing angle, high contrast ratio, low power consumption, very high response speed, lightness and thinness, flexibility, and low cost. With constant development of display technologies, a flexible display apparatus (Flexible Display) in which an OLED or a QLED is used as a light emitting device and signal control is performed through a Thin Film Transistor (TFT for short) has become a mainstream product in the field of display at present.

### SUMMARY

The following is a summary of subject matter described in the present disclosure in detail. This summary is not intended to limit the protection scope of claims.

In a first aspect, the present disclosure provides a display substrate, having a display region and a non-display region provided on and surrounding at least one side of the display region, wherein the display region is provided with pixel drive circuits arranged in an array, and the non-display region is provided with a gate drive circuit and a gating signal line group, the gating signal line group includes: a plurality of gating signal lines, and the gate drive circuit is electrically connected with the pixel drive circuit and the gating signal line group respectively;
a gating signal line extends along a first direction, the plurality of gating signal lines are arranged along a second direction, and the first direction and the second direction intersect;
the gate drive circuit includes a plurality of shift registers, a shift register includes: a gating sub-circuit, wherein the gating sub-circuit is electrically connected with a portion of the gating signal lines in the gating signal line group, the gating sub-circuit includes a plurality of gating transistors, for any shift register, the plurality of gating transistors in the gating sub-circuit are arranged along the first direction.

In an exemplary implementation, the shift register includes M gating signal terminals, and the gating signal line group includes 2M gating signal lines;
a m-th gating signal terminal is electrically connected with a (2m-1)-th gating signal line or a 2m-th gating signal line, and a signal of the (2m-1)-th gating signal line and a signal of the 2m-th gating signal line are mutually inverted signals, 1≤m≤M.

In an exemplary implementation, the non-display region has a signal line region and a device region, the gate drive circuit is at least partially located in the device region, the signal line region includes a first signal line region, a second signal line region and a third signal line region sequentially disposed along a direction close to the display region, and the device region includes a first device region, a second device region, a third device region and a fourth device region sequentially disposed along the direction close to the display region;
the first signal line region is located at a side of the first device region away from the display region, and the third signal line region is located at a side of the fourth device region close to the display region;
the gating signal line group is located in the first signal line region, and the gating sub-circuit is located in the first device region.

In an exemplary implementation, the second signal line region is located between the first signal line region and the first device region, or between the first device region and the second device region.

In an exemplary implementation, a length of the first signal line region along the second direction is greater than a length of the second signal line region along the second direction, and a length of the third signal line region along the second direction is greater than the length of the second signal line region along the second direction.

In an exemplary implementation, the non-display region is further provided with a clock signal line group, and the gate drive circuit is electrically connected with the clock signal line group;
the clock signal line group is located in the first signal line region, and is located at a side of the gating signal line group away from the display region.

In an exemplary implementation, the clock signal line group includes a control clock signal line group and an output clock signal line group;
the control clock signal line group includes a plurality of control clock signal lines, a control clock signal line extends along the first direction, the plurality of control clock signal lines are arranged along the second direction, the output clock signal line group includes a plurality of output clock signal lines, an output clock signal line extends along the first direction, the plurality of output clock signal lines are arranged along the second direction, a line width of the output clock signal line is greater than a line width of the control clock signal line and a line width of the gating signal line;
the shift register includes a plurality of control clock terminals and a plurality of output clock terminals, any one of the plurality of control clock terminals is electrically connected with one of the control clock signal lines in the control clock signal line group, and any one of the plurality of output clock terminals is electrically connected with one of the output clock signal lines in the output clock signal line group;
for any shift register, the plurality of control clock terminals are electrically connected with a portion of the signal lines in the control clock signal group, and the plurality of output clock terminals are electrically connected with a portion of the signal lines in the output clock signal line group;
the output clock signal line group is located at a side of the control clock signal line group away from the display region.

In an exemplary implementation, the non-display region is further provided with a first high-level power supply line and a second high-level power supply line;
the shift register includes: a first high-level power supply terminal and a second high-level power supply terminal; for any shift register, the first high-level power supply terminal is electrically connected with the first high-level power supply line, and the second high-level power supply terminal is electrically connected with the second high-level power supply line;
the first high-level power supply line and the second high-level power supply line are located in the second signal line region;
a line width of any one of the first high-level power supply line and the second high-level power supply line is greater than a line width of any signal line located in the first signal line region.

In an exemplary implementation, the non-display region is further provided with a first low-level power supply line and a second low-level power supply line;
the shift register includes: a first low-level power supply terminal and a second low-level power supply terminal; for any shift register, the first low-level power supply terminal is electrically connected with the first low-level power supply line, and the second low-level power supply terminal is electrically connected with the second low-level power supply line;
the first low-level power supply line and the second low-level power supply line are located in the third signal line region, and the first low-level power supply line is located at a side of the second low-level power supply line away from the display region;
a line width of any one of the first low-level power supply line and the second low-level power supply line is greater than a line width of any signal line located in the first signal line region, and a line width of the first low-level power supply line is less than a line width of the second low-level power supply line.

In an exemplary implementation, a length of the second device region along the second direction is greater than a length of the first device region along the second direction, a length of the third device region along the second direction is greater than the length of the second device region along the second direction, and a length of the fourth device region along the second direction is greater than the length of the third device region along the second direction.

In an exemplary implementation, the shift register further includes an input sub-circuit, a node setting sub-circuit, and a preprocessing sub-circuit; the plurality of control clock terminals include: a first control clock terminal to a third control clock terminal;
the node setting sub-circuit is electrically connected at least with a second high-level power supply terminal, a second low-level power supply terminal, a second control clock terminal, a third control clock terminal, a first node and a third node, respectively, and is configured to provide a signal of the second high-level power supply terminal or the second low-level power supply terminal to the first node under control of signals of the second control clock terminal, the third control clock terminal and the third node;
the input sub-circuit is at least electrically connected with the third control clock terminal, the third node and a fifth node, respectively, and is configured to provide a signal of the third control clock terminal to the fifth node under control of signals of the third node and the third control clock terminal;
the preprocessing sub-circuit is connected with at least with a second node, the third node, a fourth node, a first high-level power supply terminal and the first control clock terminal respectively, and is configured to provide a signal of the first control clock terminal or the first high-level power supply terminal to the third node and the fourth node under control of signals of the second node and the first control clock terminal;
the gating sub-circuit is further electrically connected with the second control clock terminal and the second node, respectively, and is configured to provide a signal of the second control clock terminal to the second node under control of signals of a plurality of gating signal terminals; and
the input sub-circuit, the node setting sub-circuit and the preprocessing sub-circuit are located in the second device region and arranged along the first direction, and the preprocessing sub-circuit is located between the input sub-circuit and the node setting sub-circuit.

In an exemplary implementation, the preprocessing sub-circuit includes a plurality of preprocessing transistors and a preprocessing capacitor;
the preprocessing capacitor is located at a side of the plurality of preprocessing transistors close to the node setting sub-circuit.

In an exemplary implementation, the shift register further includes a node separation sub-circuit;
the node separation sub-circuit is electrically connected with a third control clock terminal, a first high-level power supply terminal, a second low-level power supply terminal, a first node, a fifth node, a sixth node, a seventh node, an eighth node, and a ninth node, respectively, and is configured to provide a signal of the fifth node to the sixth node to the ninth node respectively under control of signals of the third control clock terminal and the first node, or to provide a signal of the first high-level power supply terminal to the fifth node under control of a signal of the sixth node; and
the node separation sub-circuit is located in the third device region.

In an exemplary implementation, the shift register further includes an output sub-circuit;
the output sub-circuit is at least electrically connected with a plurality of output clock terminals, a first low-level power supply terminal and a plurality of signal output terminals, respectively, and is configured to output a signal of a corresponding output clock terminal or the first low-level power supply terminal to the plurality of signal output terminals; and
the output sub-circuit is located in the fourth device region.

In an exemplary implementation, the output sub-circuit further includes a plurality of output capacitors arranged in an array along the first direction and the second direction.

In an exemplary implementation, the shift register further includes a reset sub-circuit and a noise reduction sub-circuit, and the plurality of control clock terminals includes: a first control clock terminal to a third control clock terminal;
the reset sub-circuit is at least electrically connected with a global reset signal terminal, a third node, a fourth node, a first high-level power supply terminal and a second low-level power supply terminal, respectively, and is configured to provide an electrical connection from the second low-level power supply terminal to the third node, the fourth node and the first high-level power supply terminal under control of a signal of the global reset signal terminal;
the noise reduction sub-circuit is electrically connected at least with a first node, a second node, a ninth node, the first control clock terminal, the second control clock terminal and the second low-level power supply terminal, respectively, and is configured to provide a signal of the second control clock terminal to the second node under control of a signal of the first control clock terminal, and provide a signal of the second low-level power supply terminal to the first node under control of a signal of the ninth node; and
the reset sub-circuit and the noise reduction sub-circuit are located in the second device region, and the reset sub-circuit and the preprocessing sub-circuit are arranged along the second direction.

In an exemplary implementation, the non-display region is further provided with a reset signal line;
a global reset signal terminal of the shift register is electrically connected with the reset signal line, and the reset signal line is located in the first signal line region.

In an exemplary implementation, the gate drive circuit includes: a plurality of shift register groups, a shift register group includes N1 shift register units, and a shift register unit includes N2 shift registers, N1, N2≥2;

A portion of gating signal lines connected with a plurality of gating signal terminals of a shift register are called gating signal line units; gating signal lines included in gating signal line units connected with any two shift registers located in a same shift register unit are the same, and at least one of gating signal lines included in gating signal line units connected with any two shift register units located in a same shift register group is different; and gating signal lines included in gating signal line units connected with n1-th shift register units located in different shift register groups are the same, 1≤n1≤N1.

In an exemplary implementation, a portion of control clock signal lines connected with a plurality of control clock terminals of a shift register are called control clock signal line units, and a portion of output clock signal lines connected with a plurality of output clock terminals of a shift register are called output clock signal line units;
at least one of control clock signal lines included in control clock signal line units connected with any two shift registers located in a same shift register unit are different, and at least one of output clock signal lines included in output clock signal line units connected with any two shift registers located in a same shift register unit are different; control clock signal lines included in control clock signal line units connected with n2-th shift registers located in different shift register units are the same, and output clock signal lines included in output clock signal line units connected with n2-th shift registers located in different shift register units are the same, 1≤n2<N2.

In an exemplary implementation, including a base substrate and a drive structure layer disposed on the base substrate, wherein the shift register includes a plurality of transistors;
the drive structure layer includes a first conductive layer, a first insulating layer, a semiconductor layer, a second insulating layer and a second conductive layer which are stacked on the base substrate;
the semiconductor layer at least includes: active patterns of a plurality of transistors in the shift register; and
the second conductive layer at least includes gate electrodes, first electrodes, and second electrodes of the plurality of transistors in the shift register.

In an exemplary implementation, further including a gating signal line, a control clock signal line, an output clock signal line, a first high-level power supply line, a second high-level power supply line, a first low-level power supply line, and a second low-level power supply line, wherein any signal line of the gating signal line, the control clock signal line, the output clock signal line, the first high-level power supply line, the second high-level power supply line, the first low-level power supply line, and the second low-level power supply line is of a single-layer structure and located in the first conductive layer, or of a double-layer structure and located in the first conductive layer and the second conductive layer.

In an exemplary implementation, the non-display region is further provided with a first connection line and a second connection line, and the first connection line and the second connection line are located in the first conductive layer;
first electrodes of all gating transistors located in a same gating sub-circuit are electrically connected with the first connection line, and second electrodes of a plurality of gating transistors located in a same gating sub-circuit are electrically connected with the second connection line; and
any electrode of a gate electrode, a first electrode and a second electrode in any gating transistor extends at least partially along the second direction, and the first connection line and the second connection line extend along the first direction.

In an exemplary implementation, the non-display region is further provided with a plurality of control clock connection lines and a plurality of control clock electrostatic release circuits; the plurality of control clock connection lines are in one-to-one correspondence with a plurality of control clock signal lines, and the plurality of control clock connection lines are in one-to-one correspondence with the plurality of control clock electrostatic release circuits;
a control clock connection line is electrically connected with a corresponding control clock signal line and a corresponding control clock electrostatic release circuit respectively.

In an exemplary implementation, the control clock connection line includes a first control clock connection part extending along the second direction and a second control clock connection part extending along the first direction;
for any control clock connection line, the first control clock connection part is electrically connected with a corresponding control clock signal line and the second control clock connection part, respectively, and the second control clock connection part is electrically connected with a corresponding control clock electrostatic release circuit; and
the first control clock connection part is located in the second conductive layer, and the second control clock connection part is located in the first conductive layer.

In an exemplary implementation, the non-display region is further provided with a plurality of output clock connection lines and a plurality of output clock electrostatic release circuits; the plurality of output clock connection lines are in one-to-one correspondence with a plurality of output clock signal lines, and the plurality of output clock connection lines are in one-to-one correspondence with the plurality of output clock electrostatic release circuits;
an output clock connection line is electrically connected with a corresponding output clock signal line and a corresponding output clock electrostatic release circuit respectively.

In an exemplary implementation, the output clock connection line includes a first output clock connection part extending along the second direction and a second output clock connection part extending along the first direction;
for any output clock connection line, the first output clock connection part is electrically connected with a corresponding output clock signal line and the second output clock connection part, respectively, and the second output clock connection part is electrically connected with a corresponding output clock electrostatic release circuit; and
the first output clock connection part is located in the second conductive layer, and the second output clock connection part is located in the first conductive layer.

In an exemplary implementation, the non-display region is further provided with four power supply connection lines and four power supply electrostatic release circuits,
a first power supply connection line is electrically connected with a first high-level power supply line and a first power supply electrostatic release circuit respectively;
a second power supply connection line is electrically connected with a second high-level power supply line and a second power supply electrostatic release circuit respectively;
a third power supply connection line is electrically connected with a first low-level power supply line and a third power supply electrostatic release circuit respectively; and
a fourth power supply connection line is electrically connected with a second low-level power supply line and a fourth power supply electrostatic release circuit respectively.

In an exemplary implementation, a power supply connection line includes a first power supply connection part extending along the second direction and a second power supply connection part extending along the first direction;
for any power supply connection line, the first power supply connection part is electrically connected with a connected power supply line and the second power supply connection part respectively, and the second power supply connection part is electrically connected with a connected power supply electrostatic release circuit; and
the first power supply connection part is located in the second conductive layer, and the second power supply connection part is located in the first conductive layer.

In an exemplary implementation, a distance between a boundary of a first signal line away from the display region and a boundary of a second signal line close to the display region is about 3400 microns to 3450 microns;
the first signal line is a signal line in a first signal line region that is farthest from a boundary of the display region, and the second signal line is a signal line in a third signal line region that is closest to the boundary of the display region.

In an exemplary implementation, signals of at least two gating signal lines are mutually inverted signals for part of a time period.

In a second aspect, the present disclosure further provides a display apparatus, including the display substrate described above.

Other aspects of the present disclosure may be comprehended after the drawings and the detailed descriptions are read and understood.

### BRIEF DESCRIPTION OF DRAWINGS

Accompany drawings are used to provide understanding of technical solution of the present disclosure, and form a part of the specification. The accompany drawings and embodiments of the present disclosure are adopted to explain the technical solution of the present disclosure, and do not form limitations on the technical solution of the present disclosure.

FIG. 1 is a schematic diagram of a structure of a display apparatus.

FIG. 2 is a first schematic diagram of a planar structure of a display substrate.

FIG. 3 is a second schematic diagram of a planar structure of a display substrate.

FIG. 4 is a third schematic diagram of a planar structure of a display substrate.

FIG. 5A is an equivalent circuit diagram of a pixel drive circuit.

FIG. 5B is a working sequence diagram of a pixel drive circuit.

FIG. 6 is an equivalent circuit diagram of a shift register.

FIG. 7 is a working time sequence diagram of the shift register provided in FIG. 6.

FIG. 8 is a first schematic structural diagram of a display substrate according to an embodiment of the present disclosure.

FIG. 9 is a second schematic structural diagram of a display substrate according to an embodiment of the present disclosure.

FIG. 10 is a top view of a gating sub-circuit.

FIG. 11 is a schematic diagram of a connection of a plurality of shift registers.

FIG. 12 is a schematic diagram of a connection of a plurality of shift register groups.

FIG. 13 is a sectional schematic diagram of a display substrate.

FIG. 14 is a partial schematic view of a non-display region of a display substrate.

FIG. 15 is a schematic diagram of a pattern of a first conductive layer in FIG. 10.

FIG. 16 is a schematic view of a pattern of a semiconductor layer in FIG. 10.

FIG. 17 is a schematic diagram after a pattern of a semiconductor is formed in FIG. 10.

FIG. 18 is a schematic diagram after a pattern of a second insulating layer is formed in FIG. 10.

FIG. 19 is a schematic diagram of a pattern of a second conductive layer in FIG. 10.

FIG. 20 is a schematic diagram after a pattern of a second conductive layer is formed in FIG. 10.

### DETAILED DESCRIPTION

To make the objectives, technical solutions, and advantages of the present disclosure clearer, the embodiments of the present disclosure will be described in detail below with reference to the accompany drawings. It is to be noted that implementation modes may be implemented in multiple different forms. Those of ordinary skills in the art can easily understand such a fact that implementation modes and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings in the embodiments of the present disclosure relate only to the structures involved in the embodiments of the present disclosure, and other structures may be described with reference to conventional designs.

Scales of the drawings in the present disclosure may be used as a reference in actual processes, but are not limited thereto. For example, a width-length ratio of a channel, a thickness and spacing of each film, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification.

In the specification, “electrical connection” includes connection of composition elements through an element with a certain electrical action. An “element with a certain electrical action” is not particularly limited as long as electrical signals between the connected constituent elements may be sent and received. Examples of the “element with the certain electrical action” not only include an electrode and a wiring, but further include a switching element such as a transistor, a resistor, an inductor, a capacitor, another element with various functions, etc.

In the specification, “parallel” refers to a state in which an angle formed by two straight lines is −10° or more and 10° or less, and thus further includes a state in which the angle is −5° or more and 5° or less. In addition, “perpendicular” refers to a state in which an angle formed by two straight lines is 80° or more and 100° or less, and thus further includes a state in which the angle is 85° or more and 95° or less.

In the specification, a “film” and a “layer” are interchangeable. For example, a “conductive layer” may be replaced with a “conductive thin film” sometimes. Similarly, an “insulation film” may be replaced with an “insulating layer” sometimes.

In the specification, “arranged in a same layer” refers to a structure formed by patterning two (or more than two) structures through a same patterning process, and their materials may be the same or different. For example, materials of precursors for forming multiple structures arranged in a same layer are the same, and final materials may be the same or different.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In the present disclosure, “about” refers to that a boundary is not defined so strictly and numerical values within a range of process and measurement errors are allowed.

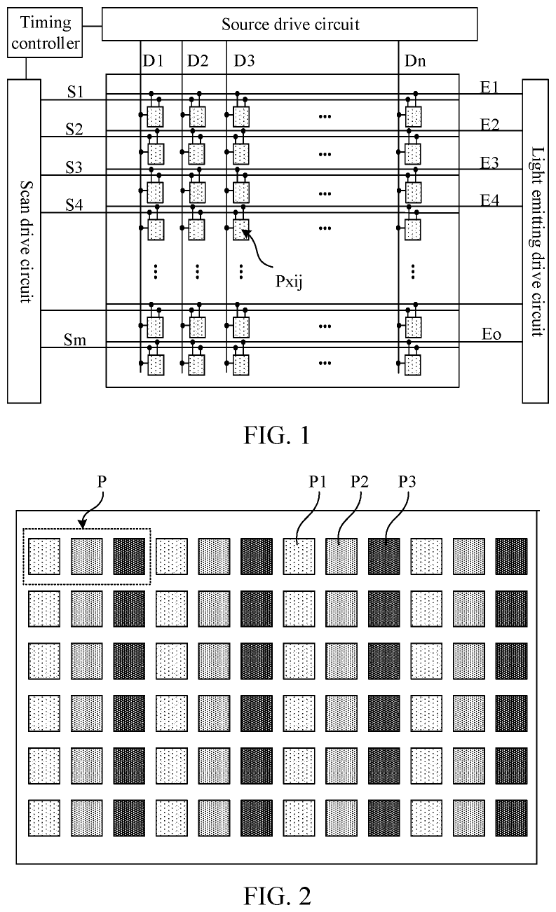

FIG. 1 is a schematic diagram of a structure of a display apparatus. As shown in FIG. 1, the display apparatus may include a timing controller, a source drive circuit, a gate drive circuit, and a pixel array, wherein the timing controller is connected with the source drive circuit and the gate drive circuit, respectively, and the source drive circuit is connected with a plurality of data signal lines (D1 to Dn), respectively. The gate drive circuit includes a scan drive circuit and a light emitting drive circuit. The scan drive circuit is respectively connected with a plurality of scan signal lines (S1 to Sm), and the light emitting drive circuit is respectively connected with a plurality of light emitting signal lines (E1 to Eo). The pixel array may include multiple sub-pixels Pxij, wherein i and j may be natural numbers. At least one sub-pixel Pxij may include a circuit unit and a light emitting device connected to the circuit unit. The circuit unit may include a pixel drive circuit, and the pixel drive circuit may be connected to a scan signal line, a light emitting signal line, and a data signal line respectively. In an exemplary implementation, the timing controller may provide a gray-scale value and a control signal suitable for a specification of the source drive circuit to the source drive circuit, provide a clock signal, a scan start signal, etc., suitable for a specification of the scan drive circuit to the scan drive circuit, and provide a clock signal, an emission stop signal, etc., suitable for a specification of the light emitting drive circuit to the light emitting drive circuit. The source drive circuit may generate a data voltage to be provided to data signal lines D1, D2, D3, . . . and Dn by using the gray-scale value and the control signal received from the timing controller. For example, the source drive circuit may sample the gray-scale value by using the clock signal and apply the data voltage corresponding to the gray-scale value to the data signal lines D1 to Dn, taking a sub-pixel line as a unit, where n may be a natural number. The scanning drive circuit may receive the clock signal, the scanning start signal, etc., from the timing controller to generate a scanning signal to be provided to the scanning signal lines S1, S2, S3, . . . and Sm. For example, the scanning drive circuit may sequentially provide a scanning signal with an on-level pulse to the scanning signal lines S1 to Sm. For example, the scan drive circuit may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting drive circuit may receive the clock signal, the emission stop signal, etc., from the timing controller to generate an emission signal to be provided to the light-emitting signal lines E1, E2, E3, . . . and Eo. For example, the light emitting drive circuit may sequentially provide an emission signal with an off-level pulse to the light-emitting signal lines E1 to Eo. For example, the light emitting drive circuit may be constructed in a form of a shift register and generate an emission signal in a manner of sequentially transmitting an emission stop signal provided in a form of an off-level pulse to a next-stage circuit under control of the clock signal, wherein o may be a natural number.

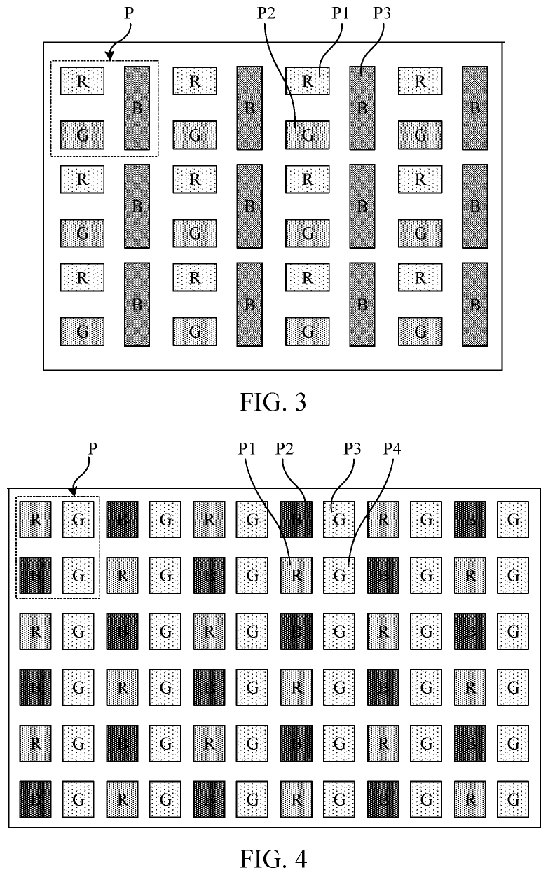

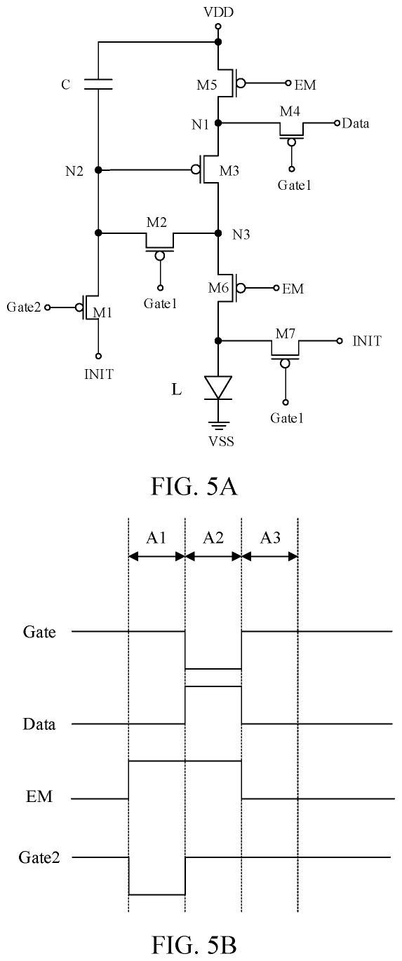

FIG. 2 is a first schematic diagram of a planar structure of a display substrate, FIG. 3 is a second schematic diagram of a planar structure of a display substrate, and FIG. 4 is a third schematic diagram of a planar structure of a display substrate. As shown in FIG. 2 to FIG. 4, the display substrate may include multiple pixel units P arranged in a matrix, at least one of the multiple pixel units P includes a first sub-pixel P1 emitting light of a first color, a second sub-pixel P2 emitting light of a second color, and a third sub-pixel P3 emitting light of a third color, and the first sub-pixel P1, the second sub-pixel P2, and the third sub-pixel P3 each includes a pixel drive circuit and a light emitting device. Pixel drive circuits in the first sub-pixel P1, the second sub-pixel P2, and the third sub-pixel P3 are connected with a scan signal line, a data signal line, and a light emitting signal line, respectively, and the pixel drive circuit is configured to receive a data voltage transmitted by the data signal line and output a corresponding current to the light emitting device under control of the scan signal line and the light emitting signal line. Light emitting devices in the first sub-pixel P1, the second sub-pixel P2, and the third sub-pixel P3 are respectively connected with the pixel drive circuit of the sub-pixel in which the light emitting device is located, and the light emitting device is configured to emit light with a corresponding brightness in response to a current outputted by the pixel drive circuit of the sub-pixel in which the light emitting device is located.

In an exemplary implementation, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light.

In exemplary embodiments, the sub-pixel may have a shape of a rectangle, a rhombus, a pentagon, or a hexagon. The present disclosure is not limited in this regard.

In an exemplary implementation, the three sub-pixels may be arranged side by side horizontally, side by side vertically, or in a form of pyramid, which is not limited in the present disclosure.

In other exemplary implementation modes, a pixel unit may include four sub-pixels, which may be arranged side by side horizontally, side by side vertically, or in a shape of a square, the present disclosure is not limited thereto.

In an exemplary implementation, the pixel drive circuit may have a structure of 3T1C, 4T1C, 5T1C, 5T2C, 6T1C, 7T1C, or 8T1C.

FIG. 5A is an equivalent circuit diagram of a pixel drive circuit. FIG. 5A is illustrated by taking a case that that the pixel drive circuit is of a structure of 7TIC as an example. As shown in FIG. 5A, the pixel drive circuit may include seven transistors (a first transistor MI to a seventh transistor M7), one storage capacitor C, and the pixel drive circuit may be connected with seven signal lines (a data signal line Data, a first scan signal line Gate1, a second scan signal line Gate2, a light emitting signal line EM, an initial signal line INIT, a first power supply line VDD, and a second power supply line VSS).

In an exemplary implementation, the pixel drive circuit may include a first node N1, a second node N2, and a third node N3. The first node N1 is connected to a first electrode of the third transistor M3, a second electrode of the fourth transistor M4 and a second electrode of the fifth transistor M5 respectively. The second node N2 is connected to a second electrode of the first transistor, a first electrode of the second transistor M2, a control electrode of the third transistor M3 and a second terminal of the storage capacitor C respectively. The third node N3 is connected to a second electrode of the second transistor M2, a second electrode of the third transistor M3 and a first electrode of the sixth transistor M6 respectively.

In an exemplary implementation, a first terminal of the storage capacitor C is connected to the first power supply line VDD, and the second terminal of the storage capacitor C is connected to the second node N2, i.e., the second terminal of the storage capacitor C is connected to the control electrode of the third transistor M3.

The control electrode of the first transistor M1 is connected with the second scan signal line Gate2, the first electrode of the first transistor M1 is connected with the initial signal line INIT, and the second electrode of the first transistor is connected with the second node N2. When a scan signal with an on-level is applied to the second scan signal line Gate2, the first transistor M1 transmits an initialization voltage to the control electrode of the third transistor M3, so as to initialize a charge amount of the control electrode of the third transistor M3.

A control electrode of the second transistor M2 is connected with the first scan signal line Gate1, a first electrode of the second transistor M2 is connected with the second node N2, and a second electrode of the second transistor M2 is connected with the third node N3. When a scan signal with an on-level is applied to the first scan signal line Gate1, the second transistor M2 enables the control electrode of the third transistor M3 to be connected with the second electrode of the third transistor M3.

A control electrode of the third transistor M3 is connected with the second node N2, i.e., the control electrode of the third transistor M3 is connected with the second terminal of the storage capacitor C, a first electrode of the third transistor M3 is connected with the first node N1, and the second electrode of the third transistor M3 is connected with the third node N3. The third transistor M3 may be referred to as a driving transistor, and the third transistor M3 determines a magnitude of a driving current flowing between the first power supply line VDD and the second power supply line VSS according to a potential difference between the control electrode and the first electrode of the third transistor M3.

A control electrode of the fourth transistor M4 is connected with the first scan signal line Gate1, a first electrode of the fourth transistor M4 is connected with the data signal line Data, and a second electrode of the fourth transistor M4 is connected with the first node N1. The fourth transistor M4 may be referred to as a switching transistor, a scan transistor, etc., and the fourth transistor M4 enables a data voltage of the data signal line Data to be input into the pixel drive circuit when a scan signal with an on-level is applied to the first scan signal line Gate1.

A control electrode of the fifth transistor M5 is connected with the light emitting signal line EM, a first electrode of the fifth transistor M5 is connected with the first power supply line VDD, and a second electrode of the fifth transistor M5 is connected with the first node N1. A control electrode of the sixth transistor M6 is connected with the light-emitting signal line EM, a first electrode of the sixth transistor M6 is connected with the third node N3, and a second electrode of the sixth transistor M6 is connected with a first electrode of a light-emitting device. The fifth transistor M5 and the sixth transistor M6 may be referred to as light emitting transistors. When a light emitting signal with an on-level is applied to the light emitting signal line EM, the fifth transistor M5 and the sixth transistor M6 enable the light emitting device to emit light by forming a drive current path between the first power supply line VDD and the second power supply line VSS.

The control electrode of the seventh transistor M7 is connected with the first scan signal line Gate1, the first electrode of the seventh transistor M7 is connected with the initial signal line INIT, and the second electrode of the seventh transistor M7 is connected with the first electrode of the light emitting device. When a scan signal with an on-level is applied to the first scan signal line Gate1, the seventh transistor M7 transmits an initialization voltage to the first electrode of the light emitting device L so as to initialize the quantity of charge accumulated in the first electrode of the light emitting device or release the quantity of charge accumulated in the first electrode of the light emitting device L.

In an exemplary implementation, a second electrode of the light emitting device L is connected with the second power supply line VSS, the second power supply line VSS continuously provides a low-level signal, and the first power supply line VDD continuously provides a high-level signal.

Transistors may be divided into N-type transistors and P-type transistors according to their characteristics. When a transistor is a P-type transistor, its turn-on voltage is a low-level voltage (e.g., 0V, −5 V, −10 V, or another suitable voltage), and its turn-off voltage is a high-level voltage (e.g., 5 V, 10 V, or another suitable voltage). When a transistor is an N-type transistor, its turn-on voltage is a high-level voltage (e.g., 5 V, 10 V, or another suitable voltage), and its turn-off voltage is a low-level voltage (e.g., 0 V, −5 V, −10 V, or another suitable voltage).

In an exemplary implementation, the first transistor M1 to the seventh transistor M7 may be P-type transistors, or may be N-type transistors. Use of a same type of transistors in a pixel drive circuit may simplify a process flow, reduce a process difficulty of a display panel, and improve a product yield. In some possible implementations, the first transistor M1 to the seventh transistor M7 may include a P-type transistor and an N-type transistor.

In an exemplary implementation, for the first transistor M1 to the seventh transistor M7, low temperature poly silicon thin film transistors may be used, or oxide thin film transistors may be used, or both a low temperature poly silicon thin film transistor and an oxide thin film transistor may be used. An active layer of a low temperature poly silicon thin film transistor is made of Low Temperature Poly silicon (LTPS for short), and an active layer of an oxide thin film transistor is made of an oxide semiconductor (Oxide). A Low temperature poly silicon thin film transistor has advantages such as a high migration rate and fast charging, and an oxide thin film transistor has advantages such as a low leakage current. The low temperature poly silicon thin film transistor and the oxide thin film transistor are integrated on one display substrate to form a Low Temperature Polycrystalline Oxide (LTPO for short) display substrate, so that advantages of both the low temperature poly silicon thin film transistor and the oxide thin film transistor may be utilized, low-frequency drive may be achieved, power consumption may be decreased, and display quality may be improved.

In an exemplary implementation, the first scan signal line Gate1, the second scan signal line Gate2, the light emitting signal line EM, and the initial signal line INIT may extend in a horizontal direction, and the second power supply line VSS, the first power supply line VDD, and the data signal line Data may extend in a vertical direction.

In an exemplary implementation, the light emitting device L may include a first electrode (anode), an organic emitting layer, and a second electrode (cathode) that are stacked.

FIG. 5B is a working sequence diagram of a pixel drive circuit. An exemplary embodiment of the present disclosure will be described below through a working process of the pixel drive circuit exemplified in FIG. 5A. The pixel drive circuit in FIG. 5 A includes seven transistors (a first transistor M1 to a seventh transistor M7) and one storage capacitor C, and the seven transistors are all P-type transistors.

In an exemplary implementation, the working process of the pixel drive circuit may include following stages.

In a first stage A1, referred to as a reset stage, a signal of the second scanning signal line Gate2 is a low-level signal, and signals of the first scanning signal line Gate1 and the light emitting signal line EM are high-level signals. The signal of the second scan signal line Gate2 is the low-level signal, so that the first transistor M1 is turned on, and a signal of the initial signal line INIT is provided to the second node N2 to initialize (reset) the storage capacitor C to clear an original charge in the storage capacitor. The signals of the first scanning signal line Gate1 and the light emitting signal line EM are the high-level signals, so that the second transistor M2, the fourth transistor M4, the fifth transistor M5, the sixth transistor M6, and the seventh transistor M7 are turned off. In this stage, the light emitting device L does not emit light.

In a second stage A2, referred to as a data writing stage or a threshold compensation stage, the signal of the first scan signal line Gate1 is a low-level signal, signals of the second scan signal line Gate2 and the light emitting signal line EM are high-level signals, and the data signal line Data outputs a data voltage. In this stage, the second terminal of the storage capacitor C is at a low level, so the third transistor M3 is turned on. The signal of the first scan signal line Gate1 is the low-level signal, so that the second transistor M2, the fourth transistor M4, and the seventh transistor M7 are turned on. The second transistor M2 and the fourth transistor M4 are turned on, so that the data voltage output by the data signal line Data is provided to the second node N2 through a first node N1, the turned-on third transistor M3, a third node N3, and the turned-on second transistor M2, and the storage capacitor C is charged with a difference between the data voltage output by the data signal line Data and a threshold voltage of the third transistor M3. A voltage at the second end (the second node N2) of the storage capacitor C is Vd-|Vth|, wherein Vd is the data voltage output by the data signal line Data, and Vth is the threshold voltage of the third transistor M3. The seventh transistor M7 is turned on, so that an initialization voltage of the initial signal line INIT is provided to a first electrode of the OLED to initialize (reset) the first electrode of the OLED and clear a pre-stored voltage therein, thereby completing initialization and ensuring that the light emitting device L does not emit light. A signal of the second scan signal line Gate2 is a high-level signal, so that the first transistor M1 is turned off. The signal of the light emitting signal line EM is the high-level signal, so that the fifth transistor M5 and the sixth transistor M6 are turned off.

In a third stage A3, referred to as a light emitting stage, the signal of the light emitting signal line EM is a low level signal, and the signals of the first scan signal line Gate1 and the second scan signal line Gate2 are high-level signals. A signal of the light emitting signal line EM is a low-level signal, so that the fifth transistor M5 and the sixth transistor M6 are turned on, and a power supply voltage outputted from the first power supply line VDD provides a driving voltage to a first electrode of the light emitting device L through the fifth transistor M5, the third transistor M3 and the sixth transistor M6 which are turned on, so as to drive the light emitting device L to emit light.

In a drive process of the pixel drive circuit, a drive current flowing through the third transistor M3 (drive transistor) is determined by a voltage difference between a gate electrode and the first electrode of the third transistor M3. The voltage of the second node N2 is Vdata-|Vth|, so the drive current of the third transistor M3 is as follows:

$$I = K * {( Vgs - Vth )}^{2} = K * {[ ( Vdd - Vd + \vert Vth \vert ) - Vth ]}^{2} = K * {( Vdd - Vd )}^{2}$$

Herein, I is the drive current flowing through the third transistor M3, i.e., a drive current for driving the OLED, K is a constant, Vgs is the voltage difference between the gate electrode and the first electrode of the third transistor M3, Vth is the threshold voltage of the third transistor M3, Vd is the data voltage output by the data signal line Data, and Vdd is the power voltage output by the first power supply line VDD.

It can be seen from the derivation result of the above current formula that in the light emitting stage, the driving current of the third transistor M3 is not affected by the threshold voltage of the third transistor M3. Therefore, the influence of the threshold voltage of the third transistor M3 on the driving current is eliminated, which can ensure uniformity of the display brightness of the display product, and improve the overall display effect of the display product.

With constant development of display technologies, the market has put forward higher requirements for low-cost, narrow bezel and thin and light design of display apparatuses. In this regard, Gate Driver on Array (GOA) technology has become a research hotspot for major manufacturers due to its advantages such as narrow bezel and thin and light design.

GOA technology integrates a gate drive circuit on an array substrate provided with a pixel array, so that the gate drive circuit can provide gate drive signals directly to the pixel array without an additional gate drive chip and a corresponding bonding structure, thereby reducing cost and reducing bezel width. The gate drive circuit is electrically connected with a first scan signal line, a second scan signal line, a reset signal line, and a light emitting signal line.

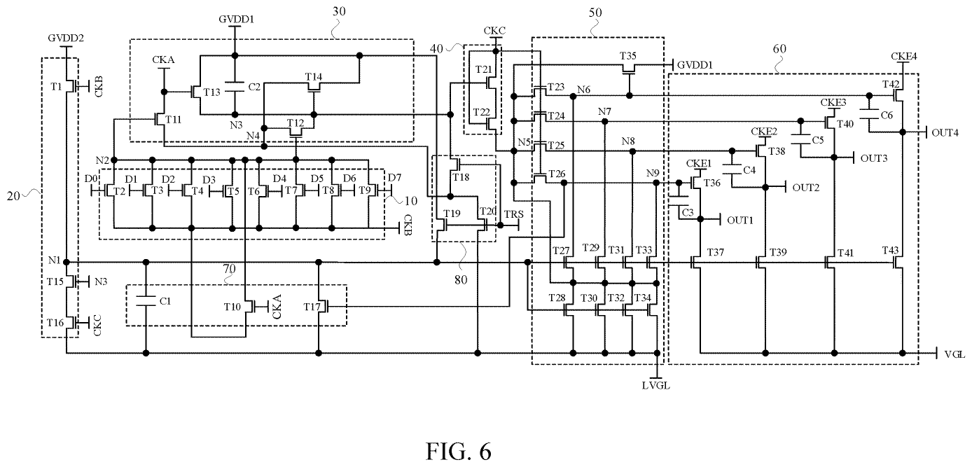

The gate drive circuit includes a plurality of shift registers. FIG. 6 is an equivalent circuit diagram of a shift register. As shown in FIG. 6, the shift register includes a gating sub-circuit 10, a node setting sub-circuit 20, a preprocessing sub-circuit 30, an input sub-circuit 40, a node separation sub-circuit 50, an output sub-circuit 60, a noise reduction sub-circuit 70, and a reset sub-circuit 80. The gating sub-circuit 10 is electrically connected with a first gating signal terminal D0 to an eighth gating signal terminal D7, a second control clock terminal CKB and a second node N2, respectively, and is configured to provide a signal of the second control clock terminal CKB to the second node N2 under control of signals of the first gating signal terminal D0 to the eighth gating signal terminal D7; the node setting sub-circuit 20 is at least electrically connected with a second high-level power supply terminal GVDD2, a second low-level power supply terminal LVGL, the second control clock terminal CKB, a third control clock terminal CKC, the first node N1 and the third node N3, respectively, and is configured to provide a signal of the second high-level power supply terminal GVDD2 or the second low-level power supply terminal LVGL to the first node N1 under control of signals of the second control clock terminal CKB, the third control clock terminal CKC and the third node N3. The input sub-circuit is at least electrically connected with the third control clock terminal CKC, the third node N3 and a fifth node N5, respectively, and is configured to provide a signal of the third control clock terminal CKC to the fifth node N3 under control of signals of the third node N3 and the third control clock terminal CKC; the preprocessing sub-circuit is at least electrically connected with the second node N2, the third node N3, a fourth node N4, a first high-level power supply terminal GVDD1, and a first control clock terminal CKA, respectively, and is configured to provide a signal of the first control clock terminal CKA or the first high-level power supply terminal GVDD1 to the third node N3 and the fourth node N4 under control of signals of the second node N2 and the first control clock terminal CKA. The node separation sub-circuit is electrically connected with the third control clock terminal CKC, the first high-level power supply terminal GVDD1, the second low-level power supply terminal LVGL, the first node N1, the fifth node N5, a sixth node N6, a seventh node N7, an eighth node N8, and a ninth node N9, respectively, and is configured to provide a signal of the fifth node N5 to the sixth node N6 to the ninth node N9 under control of signals of the third control clock terminal CKC and the first node N1, respectively, or to provide a signal of the first high-level power supply terminal GVDD2 to the fifth node N5 under control of a signal of the sixth node N6. The output sub-circuit is at least electrically connected with a first output clock terminal CKE1 to a fourth output clock terminal CKE4, a first low-level power supply terminal VGL and a first signal output terminal OUT1 to a fourth signal output terminal OUT4, respectively, and is configured to output a signal of the first output clock terminal CKE1 or the first low-level power supply terminal VGL to the first signal output terminal OUT1, output a signal of the second output clock terminal CKE2 or the first low-level power supply terminal VGL to the second signal output terminal OUT2, output a signal of the third output clock terminal CKE3 or the first low-level power supply terminal VGL to the third signal output terminal OUT3, and output a signal of the fourth output clock terminal CKE4 or the first low-level power supply terminal VGL to the fourth signal output terminal OUT4.

In an exemplary implementation, as shown in FIG. 6, the gating sub-circuit 10 at least includes a second transistor T2 to a ninth transistor T9. A gate electrode of the second transistor T2 is electrically connected with the first gating signal terminal D0, a first electrode of the second transistor T2 is electrically connected with the second control clock terminal CKB, a second electrode of the second transistor T2 is electrically connected with the second node N2, a gate electrode of the third transistor T3 is electrically connected with the second gating signal terminal D1, a first electrode of the third transistor T3 is electrically connected with the second control clock terminal CKB, a second electrode of the third transistor T3 is electrically connected with the second node N2, a gate electrode of the fourth transistor T4 is electrically connected with the third gating signal terminal D2, a first electrode of the fourth transistor T4 is electrically connected with the second control clock terminal CKB, a second electrode of the fourth transistor T4 is electrically connected with the second node N2, a gate electrode of the fifth transistor T5 is electrically connected with the fourth gating signal terminal D3, a first electrode of the fifth transistor T5 is electrically connected with the second control clock terminal CKB, a second electrode of the fifth transistor T5 is electrically connected with the second node N2, a gate electrode of the sixth transistor T6 is electrically connected with the fifth gating signal terminal D4, a first electrode of the sixth transistor T6 is electrically connected with the second control clock terminal CKB, a second electrode of the sixth transistor T6 is electrically connected with the second node N2, a gate electrode of the seventh transistor T7 is electrically connected with the sixth gating signal terminal D5, a first electrode of the seventh transistor T7 is electrically connected with the second control clock terminal CKB, a second electrode of the seventh transistor T7 is electrically connected with the second node N2, a gate electrode of the eighth transistor T8 is electrically connected with the seventh gating signal terminal D6, a first electrode of the eighth transistor T8 is electrically connected with the second control clock terminal CKB, a second electrode of the eighth transistor T8 is electrically connected with the second node N2, a gate electrode of the ninth transistor T9 is electrically connected with the eighth gating signal terminal D7, a first electrode of the ninth transistor T9 is electrically connected with the second control clock terminal CKB, and a second electrode of the ninth transistor T9 is electrically connected with the second node N2.

In an exemplary implementation, as shown in FIG. 6, the node setting sub-circuit 20 at least includes a first transistor T1, a fifteenth transistor T15, and a sixteenth transistor T16. A gate electrode of the first transistor T1 is electrically connected with the second control clock terminal CKB, a first electrode of the first transistor T1 is electrically connected with the second high-level power supply terminal GVDD2, a second electrode of the first transistor T1 is electrically connected with the first node N1, a gate electrode of the fifteenth transistor T15 is electrically connected with the third node N3, a first electrode of the fifteenth transistor T15 is electrically connected with the first node N1, a second electrode of the fifteenth transistor T15 is electrically connected with a first electrode of the sixteenth transistor T16, a gate electrode of the sixteenth transistor T16 is electrically connected with the third control clock terminal, and a second electrode of the sixteenth transistor T16 is electrically connected with the second low-level power supply terminal LVGL.

In an exemplary implementation, as shown in FIG. 6, the preprocessing sub-circuit 30 at least includes an eleventh transistor T11, a twelfth transistor T12, a thirteenth transistor T13, a tenth transistor T14, and a second capacitor C2. A gate electrode of the eleventh transistor T11 is electrically connected with the second node N2, a first electrode of the eleventh transistor T11 is electrically connected with the first control clock terminal CKA, a second electrode of the eleventh transistor T11 is electrically connected with the fourth node N4, a gate electrode of the twelfth transistor T12 is electrically connected with the second node N2, a first electrode of the twelfth transistor T12 is electrically connected with the fourth node N4, a second electrode of the twelfth transistor T12 is electrically connected with the third node N3, a gate electrode of the thirteenth transistor T13 is electrically connected with the first control clock terminal CKA, a first electrode of the thirteenth transistor T13 is electrically connected with the third node N3, a second electrode of the thirteenth transistor T13 is electrically connected with the first high-level power supply terminal GVDD1, a gate electrode of the fourteenth transistor T14 is electrically connected with the third node N3, a first electrode of the fourteenth transistor T14 is electrically connected with the fourth node N4, a second electrode of the fourteenth transistor T14 is electrically connected with the first high-level power supply terminal GVDD1, a first terminal of the second capacitor C2 is electrically connected with the third node N3, and a second terminal of the second capacitor C2 is electrically connected with the first high-level power supply terminal GVDD1.

In an exemplary implementation, as shown in FIG. 6, the input sub-circuit 40 at least includes a twenty-first transistor T21 and a twenty-second transistor T22. A gate electrode of the twenty-first transistor T21 is electrically connected with the third node N3, a first electrode of the twenty-first transistor T21 is electrically connected with the third control clock terminal CKC, a second electrode of the twenty-first transistor T21 is electrically connected with a first electrode of the twenty-second transistor T22, a gate electrode of the twenty-second transistor T22 is electrically connected with the third control clock terminal CKC, and a second electrode of the twenty-second transistor T22 is electrically connected with the fifth node N5.

In an exemplary implementation, as shown in FIG. 6, the node separation sub-circuit 50 at least includes a twenty-third transistor T23 to a thirty-fifth transistor T35. A control electrode of the twenty-third transistor T23 is electrically connected with the third control clock terminal CKC, a first electrode of the twenty-third transistor T23 is electrically connected with the fifth node N5, a second electrode of the twenty-third transistor T23 is electrically connected with the sixth node N6, a control electrode of the twenty-fourth transistor T24 is electrically connected with the third control clock terminal CKC, a first electrode of the twenty-fourth transistor T24 is electrically connected with the fifth node N5, a second electrode of the twenty-fourth transistor T24 is electrically connected with the seventh node N7, a control electrode of the twenty-fifth transistor T25 is electrically connected with the third control clock terminal CKC, a first electrode of the twenty-fifth transistor T25 is electrically connected with the fifth node N5, a second electrode of the twenty-fifth transistor T25 is electrically connected with the eighth node N8, a control electrode of the twenty-sixth transistor T26 is electrically connected with the third control clock terminal CKC, a first electrode of the twenty-sixth transistor T26 is electrically connected with the fifth node N5, a second electrode of the twenty-sixth transistor T26 is electrically connected with the ninth node N9, a control electrode of the twenty-seventh transistor T27 is electrically connected with the first node N1, a first electrode of the twenty-seventh transistor T27 is electrically connected with the sixth node N6, a second electrode of the twenty-seventh transistor T27 is electrically connected with the fifth node N5, a control electrode of the twenty-eighth transistor T28 is electrically connected with the first node N1, a first electrode of the twenty-eighth transistor T28 is electrically connected with the fifth node N5, a second electrode of the twenty-eighth transistor T28 is electrically connected with the second low-level power supply terminal LVGL, a control electrode of the twenty-ninth transistor T29 is electrically connected with the first node N1, a first electrode of the twenty-ninth transistor T29 is electrically connected with the seventh node N7, a second electrode of the twenty-ninth transistor T29 is electrically connected with the fifth node N5, a control electrode of the thirtieth transistor T30 is electrically connected with the first node N1, a first electrode of the thirtieth transistor T30 is electrically connected with the fifth node N5, a second electrode of the thirtieth transistor T30 is electrically connected with the second low-level power supply terminal LVGL, a control electrode of the thirty-first transistor T31 is electrically connected with the first node N1, a first electrode of the thirty-first transistor T31 is electrically connected with the sixth node N6, a second electrode of the thirty-first transistor T31 is electrically connected with the eighth node N8, a control electrode of the thirty-second transistor T32 is electrically connected with the first node N1, a first electrode of the thirty-second transistor T32 is electrically connected with the fifth node N5, a second electrode of the thirty-second transistor T32 is electrically connected with the second low-level power supply terminal LVGL, a control electrode of the thirty-third transistor T33 is electrically connected with the first node N1, a first electrode of the thirty-third transistor T33 is electrically connected with the ninth node N9, a second electrode of the thirty-third transistor T33 is electrically connected with the fifth node N5, a control electrode of the thirty-fourth transistor T34 is electrically connected with the first node N1, a first electrode of the thirty-fourth transistor T34 is electrically connected with the fifth node N5, a second electrode of the thirty-fourth transistor T34 is electrically connected with the second low-level power supply terminal LVGL, a gate electrode of the thirty-fifth transistor T35 is electrically connected with the sixth node N6, a first electrode of the thirty-fifth transistor T35 is electrically connected with the first high-level power supply terminal GVDD1, and a second electrode of the thirty-fifth transistor T35 is electrically connected with the fifth node N5.

In an exemplary implementation, as shown in FIG. 6, the output sub-circuit 60 at least includes a thirty-sixth transistor T36, a thirty-seventh transistor T37, a thirty-eighth transistor T38, a thirty-ninth transistor T39, a fortieth transistor T40, a forty-first transistor T41, a forty-second transistor T42, a forty-third transistor T43, a third capacitor C3, a fourth capacitor C4, a fifth capacitor C5, and a sixth capacitor C6. A gate electrode of the thirty-sixth transistor T36 is electrically connected with the ninth node N9, a first electrode of the thirty-sixth transistor T36 is electrically connected with the first output clock terminal CKE1, a second electrode of the thirty-sixth transistor T36 is electrically connected with the first output terminal OUT1, a gate electrode of the thirty-seventh transistor T37 is electrically connected with the first node N1, a first electrode of the thirty-seventh transistor T37 is electrically connected with the first output terminal OUT1, a second electrode of the thirty-seventh transistor T37 is electrically connected with the first low-level power supply terminal VGL, a gate electrode of the thirty-eighth transistor T38 is electrically connected with the eighth node N8, a first electrode of the thirty-eighth transistor T38 is electrically connected with the second output clock terminal CKE2, a second electrode of the thirty-eighth transistor T38 is electrically connected with the second output terminal OUT2, a gate electrode of the thirty-ninth transistor T39 is electrically connected with the first node N1, a first electrode of the thirty-ninth transistor T39 is electrically connected with the second output terminal OUT2, a second electrode of the thirty-ninth transistor T39 is electrically connected with the first low-level power supply terminal VGL, a gate electrode of the forty-transistor T40 is electrically connected with the seventh node N7, a first electrode of the forty-transistor T40 is electrically connected with the third output clock terminal CKE3, a second electrode of the forty-transistor T40 is electrically connected with the third output terminal OUT3, a gate electrode of the forty-first transistor T41 is electrically connected with the first node N1, a first electrode of the forty-first transistor T41 is electrically connected with the third output terminal OUT3, a second electrode of the forty-first transistor T41 is electrically connected with the first low-level power supply terminal VGL, a gate electrode of the forty-second transistor T42 is electrically connected with the sixth node N6, a first electrode of the forty-second transistor T42 is electrically connected with the fourth output clock terminal CKE4, a second electrode of the forty-second transistor T42 is electrically connected with the fourth output terminal OUT4, a gate electrode of the forty-third transistor T43 is electrically connected with the first node N1, a first electrode of the forty-third transistor T43 is electrically connected with the fourth output terminal OUT4, a second electrode of the forty-third transistor T43 is electrically connected with the first low-level power supply terminal VGL, a first terminal of the third capacitor C3 is electrically connected with the ninth node N9, a second terminal of the third capacitor C3 is electrically connected with the first output terminal OUT1, a first terminal of the fourth capacitor C4 is electrically connected with the eighth node N8, a second terminal of the fourth capacitor C4 is electrically connected with the second output terminal OUT2, a first terminal of the fifth capacitor C5 is electrically connected with the seventh node N7, a second terminal of the fifth capacitor C5 is electrically connected with the third output terminal OUT3, a first terminal of the sixth capacitor C6 is electrically connected with the sixth node N6, and a second terminal of the sixth capacitor C6 is electrically connected with the fourth output terminal OUT4.

In an exemplary implementation, as shown in FIG. 6, the noise reduction sub-circuit 70 at least includes a tenth transistor T10, a seventeenth transistor T17, and a first capacitor C1. A gate electrode of the tenth transistor T10 is electrically connected with the first control clock terminal CKA, a first electrode of the tenth transistor T10 is electrically connected with the second control clock terminal CKB, a second electrode of the tenth transistor T10 is electrically connected with the second node N2, a gate electrode of the seventeenth transistor T17 is electrically connected with the ninth node N9, a first electrode of the seventeenth transistor T17 is electrically connected with the first node N1, a second electrode of the seventeenth transistor T17 is electrically connected with the second low-level power supply terminal LVGL, a first terminal of the first capacitor C1 is electrically connected with the first node N1, and a second terminal of the first capacitor C1 is electrically connected with the second low-level power supply terminal LVGL.

In an exemplary implementation, as shown in FIG. 6, the reset sub-circuit 80 at least includes an eighteenth transistor T18, a nineteenth transistor T19, and a twentieth transistor T20. A gate electrode of the eighteenth transistor T18 is electrically connected with a global reset signal terminal TRS, a first electrode of the eighteenth transistor T18 is electrically connected with the third node N3, a second electrode of the eighteenth transistor T18 is electrically connected with the fourth node N4, a gate electrode of the nineteenth transistor T19 is electrically connected with the global reset signal terminal TRS, a first electrode of the nineteenth transistor T19 is electrically connected with the first high-level power supply terminal GVDD1, a second electrode of the nineteenth transistor T19 is electrically connected with the first node N1, a gate electrode of the twentieth transistor T20 is electrically connected with the global reset signal terminal TRS, a first electrode of the twentieth transistor T20 is electrically connected with the fourth node N4, and a second electrode of the twentieth transistor T20 is electrically connected with the second low-level power supply terminal LVGL.

In an exemplary implementation, all transistors in the shift register, i.e., the first transistor T1 to the forty-third transistor T43, may be N-type transistors. Use of the same type of transistors in the shift register may simplify process flows, decrease process difficulties of the display panel, and improve the product yield rate.

In an exemplary implementation, a gate drive circuit including the shift register provided in FIG. 6 may be located in a large size display product, and the pixel drive circuit in a large size display product may have a structure of 3T1C. The present disclosure is not limited in this regard.

In an exemplary implementation, signals of the first high-level power supply terminal GVDD1 and the second high-level power supply terminal GVDD2 are DC signals and are high-level signals.

In an exemplary implementation, signals of the first low-level power supply terminal VGL and the second low-level power supply terminal LVGL are DC signals and are low-level signals, and an absolute value of a voltage value of the signal of the second low-level power supply terminal LVGL is greater than an absolute value of a voltage value of the signal of the first low-level power supply terminal VGL.

In an exemplary implementation, a signal of any signal terminal of the first control clock terminal CKA to the third control clock terminal CKC and the first output clock terminal CK1 to the fourth output clock terminal CK4 is a square wave signal repeating a high voltage and a low voltage. Exemplarily, signals of any two signal terminals of the first control clock terminal CKA to the third control clock terminal CKC may have the same cycle and may be configured as phase shift signals. Signals of any two signal terminals of the first output clock terminal CK1 to the fourth output clock terminal CK4 may have the same cycle and may be configured as phase-shifted signals.

In an exemplary implementation, a high-voltage period of a signal of the first control clock terminal CKA may be overlapped with part of a low-voltage period of a signal of the second control clock terminal CKB and part of a low-level period of a signal of the third control clock terminal CKC. A high-voltage period of the signal of the second control clock terminal CKB may be overlapped with part of a low-voltage period of the signal of the first control clock terminal CKA and part of the low-level period of the signal of the third control clock terminal CKC. A high-voltage period of a signal of the third control clock terminal CKC may be overlapped with part of the low-voltage period of the signal of the first control clock terminal CKA and part of a low-level period of the signal of the second control clock terminal CKB.

In an exemplary implementation, a high-voltage period of a signal of the first output clock terminal CKE1 may be partially overlapped with a high-voltage period of a signal of the second output clock terminal CKE2, the high-voltage period of the signal of the second output clock terminal CKE2 may be partially overlapped with a high-voltage period of a signal of the third output clock terminal CKE3, the high-voltage period of the signal of the third output clock terminal CKE3 may be partially overlapped with a high-voltage period of a signal of the fourth output clock terminal CKE4, and the high-voltage period of the signal of the first output clock terminal CKE1 is not overlapped with the high-voltage period of the signal of the fourth output clock terminal CKE4.

In an exemplary implementation, any of the first capacitor C1 to sixth capacitor C6 may be a capacitor device fabricated by a process, for example, the capacitor device may be implemented by fabricating a special capacitor electrode, and a plurality of capacitor electrodes of the capacitor may be implemented by metal layers, semiconductor layers (e.g. doped polysilicon), or the like. Alternatively, any of the first capacitor C1 to the sixth capacitor C6 may be a parasitic capacitance between a plurality of devices, and may be implemented by the transistor itself and other devices or lines. The connection mode of any of the first capacitor C1 to the sixth capacitor C6 includes but is not limited to the mode described above, and may be another suitable connection mode which may store the level of the corresponding node. Herein, the illustrative embodiments of the present disclosure are not limited thereto.

In an exemplary implementation, the shift register may include a plurality of gating signal terminals. FIG. 6 is illustrated by taking eight gating signal terminals as an example. In an exemplary implementation, gating signals available for access at any gating signal terminal in the shift register include two gating signals, and the two gating signals are inverted signals. The two gating signals accessed at different gating signal terminals are different, and there is no output from the shift register only when signals of all gating signal terminals are ineffective level signals. The setting of the plurality of gating signal terminals can realize that at least a portion of the shift registers in the gate drive circuit can operate independently, and there is no cascading relationship between adjacent shift registers. When the gating sub-circuit includes 8 transistors, the independent operation of 2\hat{ }8=256 shift registers can be realized.

In an exemplary implementation, the shift register may include a plurality of output terminals, each of which is connected with a row of sub-pixels. The shift register provided in FIG. 6 includes four output terminals, that is, four rows of sub-pixels are connected, that is, when the gating sub-circuit includes 8 transistors, independent operation of 2\hat{ }=1024 rows of sub-pixels can be achieved. If a quantity of rows of sub-pixels that can independently operate is to be increased, this may be achieved by increasing the quantity of transistors included in the gating sub-circuit or by increasing the quantity of output terminals. For example, the gating sub-circuit may include 10 transistors, which is not limited in the present disclosure.

The shift register provided by the present disclosure can ensure that a plurality of shift registers do not need to be cascaded, thereby allowing the shift registers to operate independently. This enables the gate drive circuit using the shift register provided in FIG. 6 can randomly gate a certain row of sub-pixels. Thus, on the one hand, the gate drive circuit using the shift register provided in FIG. 6 can perform local refreshes on a display picture without performing row-by-row scanning, thereby significantly increasing the refresh rate; for example, when only a portion of the display picture needs to be refreshed, only a portion of the display picture can be targeted to be refreshed, thereby greatly improving the refresh rate.

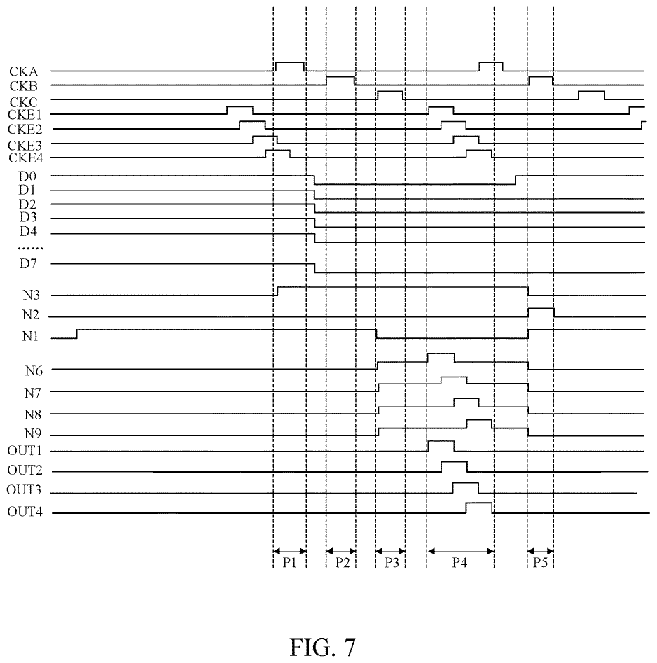

FIG. 7 is a working time sequence diagram of the shift register provided in FIG. 6. As shown in FIG. 7, an exemplary embodiment of the present disclosure will be described below by a working process of the shift register exemplified in FIG. 6, which includes 43 transistors (the first transistor T1 to the forty-third transistor T43) and six capacitors C (the first capacitor C1 to the sixth capacitor C6), and the 43 transistors are all P-type transistors.

In an exemplary implementation, the working process of the shift register may include a display stage and a non-display stage, wherein a signal of the global reset signal terminal TRS is a high-level signal in a portion of the non-display stage and a low-level signal in the display stage. Signals of the first control clock terminal CKA to the third control clock terminal CKC and the first output clock terminal CKE1 to the fourth output clock terminal CKE4 are low-level signals, and signals of the first gating signal terminal D0 to the eighth gating signal terminal D7 are high-level signals. According to the principle of gating, the shift register will not be gated when signals of all gating signal terminals are high-level signals.

In the non-display stage, a signal of the global reset signal terminal TRS is a high-level signal, and signals of the first gating signal terminal D0 to the eighth gating signal terminal D7 are high-level signals. The signal of the global reset signal terminal TRS is a high-level signal, the eighteenth transistor T18 and the twentieth transistor T20 are turned on, signals of the third node N3 and the fourth node N4 are pulled down by the second low-level power supply terminal LVGL to become low-level signals, the nineteenth transistor T19 is turned on, the first node N1 is pulled up by the high level of the first high-level power supply GVDD1, the twenty-seventh transistor 27 to the thirty-fourth transistor T34 are turned on, the thirty-seventh transistor T37, the thirty-ninth transistor T39, the forty-first transistor T41 and the forty-third transistor T43 are turned on, signals of the sixth node N6, the seventh node N7, the eighth node N8 and the ninth node N9 are pulled down by the second low-level power supply terminal LVGL to become low-level signals, and signals of the first output terminal OUT1 to the fourth output terminal OUT4 are pulled down by the first low-level power supply terminal VGL. Signals of the first gating signal terminal D0 to the eighth gating signal terminal D7 are high-level signals, the second transistor T2 to the ninth transistor T9 are turned on, and a signal of the second node N2 is pulled down by the second control clock terminal CKB.

In an exemplary implementation, the working process of the shift register in the display stage may include following stages.

In a first stage P1, signals of the first control clock terminal CKA and the first gating signal terminal D0 to the eighth gating signal terminal D7 are high-level signals, and signals of the second control clock terminal CKB and the third control clock terminal CKC are low-level signals. Under the action of the first capacitor C1, the first node N1 maintains a high-level signal, the twenty-seventh T27 to the thirty-fourth transistors to T34 are turned on, the thirty-seventh transistor T37, the thirty-ninth transistor T39, the forty-first transistor T41, and the forty-third transistor T43 are continuously turned on, signals of the sixth node N6, the seventh node N7, the eighth node N8, and the ninth node N9 are continuously pulled down by the second low-level power supply terminal LVGL to become low-level signals, and signals of the first output terminals OUT1 to the fourth output terminal OUT4 are continuously pulled down by the first low-level power supply terminal VGL. The signals of the first gating signal terminal D0 to the eighth gating signal terminal D7 are high-level signals, the second transistor T2 to the ninth transistor T9 are turned on, the signal of the second node N2 is pulled down by the second control clock terminal CKB, and the signal of the second node N2 is a low-level signal. The signal of the first control clock terminal CKA is a high-level signal, the thirteenth transistor T13 is turned on, the third node N3 is pulled up by the signal of the first high-level power supply terminal GVDD1, a signal of the third node N3 is a high-level signal, a signal of the twenty-first transistor T21 is turned on, a signal of the third control clock terminal CKC is a low-level signal, the twenty-second transistor T22 to the twenty-sixth transistor T26 are turned off, the fourteenth transistor T14 is turned on, a signal of the fourth node N4 is pulled up by the signal of the first high-level power supply terminal GVDD1, the signal of the fourth node N4 is a high-level signal, in this stage, a signal of the first node N1 is a high-level signal, the signal of the second node N2 is a low-level signal, the signal of the third node N3 is a high-level signal, the signal of the fourth node N4 is a high-level signal, and the first output terminal OUT1 to the fourth output terminal OUT4 have no output.

In a second stage P2, the signal of the second control clock terminal CKB is a high-level signal, and signals of the first gating signal terminal D0 to the eighth gating signal terminal D7, the second control clock terminal CKB and the third control clock terminal CKC are low-level signals. The signal of the second control clock terminal CKB is a high-level signal, the first transistor T1 is turned on, the signal of the first node N1 is pulled up by the high level of the second high-level power supply terminal GVDD2, the twenty-seventh transistor T27 to the thirty-fourth transistor T34 are turned on, the thirty-seventh transistor T37, the thirty-ninth transistor T39, the forty-first transistor T41 and the forty-third transistor T43 are continuously turned on, signals of the sixth node N6, the seventh node N7, the eighth node N8 and the ninth node N9 are continuously pulled down by the second low-level power supply terminal LVGL to become low-level signals, and signals of the first output terminal OUT1 to the fourth output terminal OUT4 are continuously pulled down by the first low-level power supply terminal VGL. Since the signals of the first gating signal terminal D0 to the eighth gating signal terminal D7 are low-level signals, the second transistor T2 to the ninth transistor T9 are turned off, the high-level signal of the second control clock terminal CKB cannot be written into the second node N2, and the third nodes N3 and the fourth nodes N4 maintain high-level signals of a previous stage. In this stage, the signal of the first node N1 is a high-level signal, the signal of the second node N2 is a low-level signal, the signal of the third node N3 is a high-level signal, and the signal of the fourth node N4 is a high-level signal. The first output terminal OUT1 to the fourth output terminal OUT4 have no output.

In a third stage P3, the signal of the third control clock terminal CKC is a high-level signal. Signals of the first control clock terminal CKA, the second control clock terminal CKB, and the first gating signal terminal D0 to the eighth gating signal terminal D7 are low-level signals. The second node N2 maintain a low-level signal of a previous stage, the third node N3 and the fourth node N4 maintain high-level signals of a previous stage, the signal of the third control clock terminal CKC is a high-level signal, the fifteenth transistor T15 and the sixteenth transistor T16 are turned on, the signal of the first node N1 is pulled down by the second low-level power supply GVDD2, the twenty-seventh transistor T27 to the thirty-fourth transistor T34 is turned on, the thirty-seventh transistor T37, the thirty-ninth transistor T39, the forty-first transistor T41 and the forty-third transistor T43 is turned off, the twenty-first transistor T21 to the twenty-sixth transistor T26 are turned on, the fifth node N5 is pulled up by the high-level signal of the third control clock terminal CKC, the sixth node N6 to the ninth node N9 are pulled up by a signal of the fifth node N5, the thirty-sixth transistor T36, the thirty-eighth transistor T38, the fortieth transistor T40 and the forty-second transistor T42 are turned on, since the signals of the first output clock terminal CKE1 to the fourth output clock terminal CKE4 are low-level signals, the signals of the first output terminal OUT1 to the fourth output terminal OUT4 are low-level signals.

In a fourth stage P4, the signals of the first output clock terminal CKE1 to the fourth output clock terminal CKE4 are high-level signals for part of a time period, signals of the first control clock terminal CKA to the third control clock terminal CKC and the first gating signal terminal D0 to the eighth gating signal terminal D7 are low-level signals, under the bootstrapping action of the third capacitor C3, the ninth node N9 is raised, the thirty-sixth transistor T36 is turned on, the high-level signal of the first output clock terminal CKE1 is written into the first output terminal OUT1, under the bootstrapping action of the fourth capacitor C4, the eighth node N8 is raised, the thirty-eighth transistor T38 is turned on, the high-level signal of the second output clock terminal CKE2 is written into the second output terminal OUT2, under the bootstrapping action of the fifth capacitor C5, the seventh node N7 is raised, the fortieth transistor T40 is turned on, the high-level signal of the third output clock terminal CKE3 is written into the third output terminal OUT3, under the bootstrapping action of the fourth capacitor C4, the sixth node N6 is raised, the forty-second transistor T42 is turned on, the high-level signal of the fourth output clock terminal CKE4 is written to the fourth output terminal OUT4, the thirty-fifth transistor T35 is continuously turned on, the signal of the fifth node N5 is continuously pulled high, in this stage, the signals of the first node N1 and the second node N2 are low-level signals, the signals of the third node N3 to the ninth node N9 are high-level signals, and the signals of the first output terminal OUT1 to the fourth output terminal OUT4 are high-level signals.

In a fifth stage P5, signals of the second control clock terminal CKB and the first gating signal terminal D0 are high-level signals, and signals of the first control clock terminal CKA, the third control clock terminal CKB, the second gating signal terminal D1 to the eighth gating signal terminal D7 are low-level signals. The signal of the second control clock terminal CKB is a high-level signal, the first transistor T1 is turned on, the signal of the first node N1 is pulled up by the high level of the second high-level power supply terminal GVDD2, the twenty-seventh transistor T27 to the thirty-fourth transistor T34 are turned on, the thirty-seventh transistor T37, the thirty-ninth transistor T39, the forty-first transistor T41 and the forty-third transistor T43 are continuously turned on, the signals of the sixth node N6, the seventh node N7, the eighth node N8 and the ninth node N9 are continuously pulled down by the second low-level power supply terminal LVGL to become low-level signals, and the signals of the first output terminal OUT1 to the fourth output terminal OUT4 are continuously pulled down by the first low-level power supply terminal VGL. Since the signal of the first gating signal terminal D0 is a high-level signal, the second transistor T2 is turned on, the high-level signal of the second control clock terminal CKB is written to the second node N2, the eleventh transistor T11 and the twelfth transistor T12 are turned on, and the low-level signal of the first control clock terminal CKA is written to the third node N3 and the fourth node N4. In this stage, the signals of the first node N1 and the second node N2 are high-level signals, the signals of the third node N3 and the fourth node N4 are low-level signals, and the first output terminals OUT1 to the fourth output terminals OUT4 have no output.

The above explanation is given by taking a case that the signals of the first gating signal terminal D0 to the eighth gating signal terminal D7 of the shift register are all low-level signals in the second stage as an example.

For a shift register in which a signal of one of the first gating signal terminal D0 to the eighth gating signal terminal D7 is a high-level signal in the second stage, in the second stage, the signal of the second control clock terminal CKB is a high-level signal, the first transistor T1 is turned on, the signal of the first node N1 is pulled up by the high level of the second high-level power supply terminal GVDD2, the twenty-seventh transistor T27 to the thirty-fourth transistor T34 is turned on, the thirty-seventh transistor T37, the thirty-ninth transistor T39, the forty-first transistor T41 and the forty-third transistor T43 are continuously turned on, the signals of the sixth node N6, the seventh node N7, the eighth node N8 and the ninth node N9 are continuously pulled down by the second low-level power supply terminal LVGL to become low-level signals, and the signals of the first output terminal OUT1 to the fourth output terminal OUT4 are continuously pulled down by the first low-level power supply terminal VGL. Since a signal of one of the first gating signal terminal D0 to the eighth gating signal terminal D7 is a high-level signal, one of the second transistor T2 to the ninth transistor T9 is turned on, the high-level signal of the second control clock terminal CKB is written to the second node N2, the eleventh transistor T11 and the twelfth transistor T12 are turned on, and the low-level signal of the first control clock terminal CKA is written to the third node N3 and the fourth node N4. In this stage, the signals of the first node N1 and the second node N2 are high-level signals, the signals of the third node N3 and the fourth node N4 are low-level signals, the first output terminals OUT1 to the fourth output terminal OUT4 have no output, until signals of all gating signal terminals are low-level signals. Only then does the execution of the third stage commence, initiating output.

In summary, when signals of all gating signal terminals in the shift register are low-level signals, the shift register starts to output, and when at least one of the signals of all the gating signal terminals in the shift register is a high-level signal, the shift register does not output.

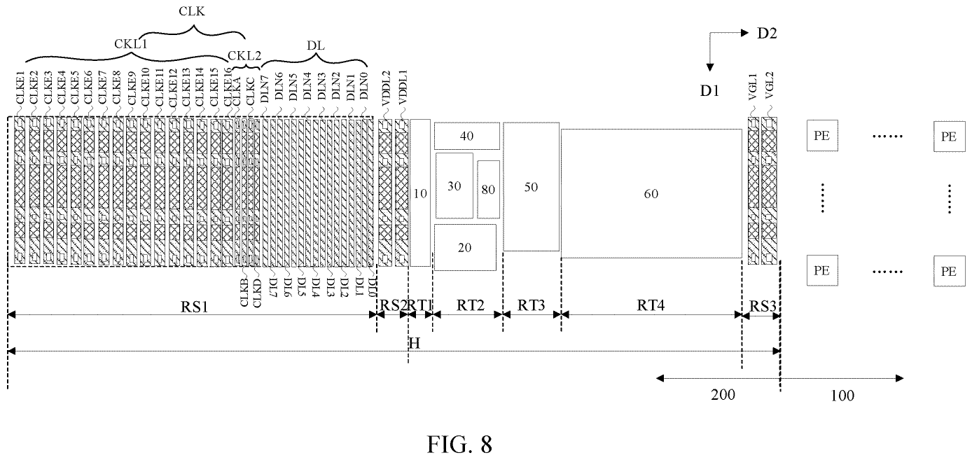

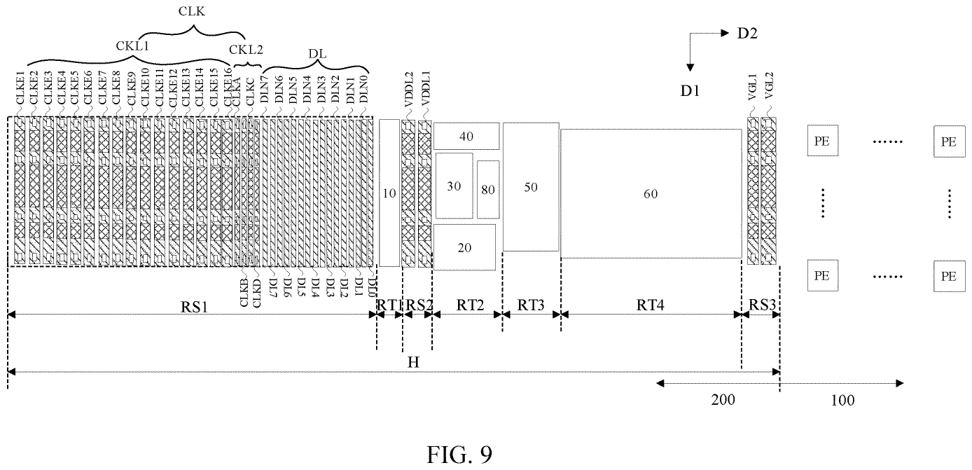

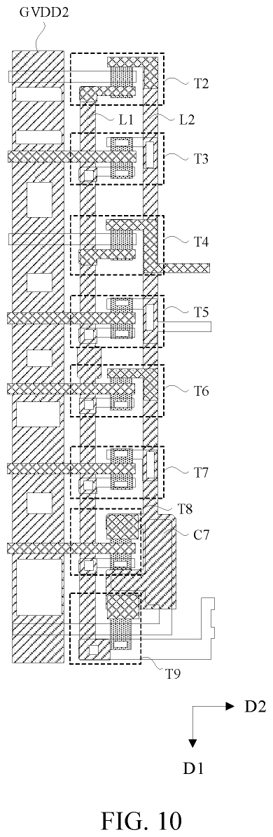

The display apparatus includes the gate drive circuit provided in FIG. 6. Due to a large number of transistors included in the shift register within the gate driver circuit, the display apparatus is unable to achieve a narrow bezel.
FIG. 8 is a first schematic structural diagram of a display substrate according to an embodiment of the present disclosure, FIG. 9 is a second schematic structural diagram of a display substrate according to an embodiment of the present disclosure, and FIG. 10 is a top view of a gating sub-circuit. As shown in FIGS. 8 to 10, a display substrate according to an embodiment of the present disclosure has a display region 100 and a non-display region 200 provided on and surrounding at least one side of the display region 100. The display region 100 is provided with pixel drive circuits PE arranged in an array, and the non-display region 200 is provided with a gate drive circuit and a gating signal line group DL. The gating signal line group DL includes a plurality of gating signal lines, and the gate drive circuit is electrically connected with the pixel drive circuits and the gating signal line group DL, respectively. A gating signal line extends along a first direction D1, and the plurality of gating signal lines are arranged along a second direction D2, wherein the first direction D1 and the second direction D2 intersect.

Exemplarily, the first direction D1 may be a column direction, and the second direction D2 may be a row direction. The first direction intersecting the second direction means that an angle between the first direction and the second direction is about 70 degrees to 90 degrees. The first direction and the second direction may be in a same plane.

FIGS. 8 and 9 are illustrated by taking a case that sixteen gating signal lines are a first gating signal line DL0, a second gating signal line DLN0, a third gating signal line DL1, a fourth gating signal line DLN1, a fifth gating signal line DL2, a sixth gating signal line DLN2, a seventh gating signal line DL3, an eighth gating signal line DLN3, a ninth gating signal line DLA, a tenth gating signal line DLN4, an eleventh gating signal line DL5, a twelfth gating signal line DLN5, a thirteenth gating signal line DL6, a fourteenth gating signal line DLN6, a fifteenth gating signal line DL7 and a sixteenth gating signal line DLN7, respectively, as an example.

As shown in FIGS. 8 to 10, the gate drive circuit includes a plurality of shift registers, and a shift register includes a gating sub-circuit 10, the gating sub-circuit is electrically connected with a portion of the gating signal lines in the gating signal line group DL, the gating sub-circuit may include a plurality of gating transistors, and for any of the shift registers, the plurality of gating transistors in the gating sub-circuit are arranged along the first direction D1. Exemplarily, the plurality of gating transistors are the second transistor T2 to the ninth transistor T9 in FIG. 6, that is, the second transistor T2 to the ninth transistor T9 are arranged along the first direction D1. FIGS. 8 and 9 show only one shift register.

In an exemplary implementation, the gate drive circuit may be located on at least one side of the display region 200, which is not limited in present disclosure.

The display substrate according to an embodiment of the present disclosure has a display region and a non-display region provided on and surrounding at least one side of the display region, wherein the display region is provided with pixel drive circuits arranged in an array, and the non-display region is provided with a gate drive circuit and a gating signal line group, the gating signal line group includes: a plurality of gating signal lines, and the gate drive circuit is electrically connected with the pixel drive circuits and the gating signal line group respectively; a gating signal line extends along a first direction, the plurality of gating signal lines are arranged along a second direction, and signals of at least two gating signal lines are mutually inverted signals, the gate drive circuit includes a plurality of shift registers, a shift register includes: a gating sub-circuit, wherein the gating sub-circuit is electrically connected with a portion of the gating signal lines in the gating signal line group, the gating sub-circuit includes a plurality of gating transistors, for any shift register, the plurality of gating transistors in the gating sub-circuit are arranged along the first direction. By arranging the plurality of gating transistors in the gating sub-circuit in any shift register along the first direction, the present disclosure can reduce a length of the gate drive circuit along the second direction, thereby realizing a narrow bezel of the display substrate.

In an exemplary implementation, signals of at least two gating signal lines are mutually inverted signals for part of a time period.

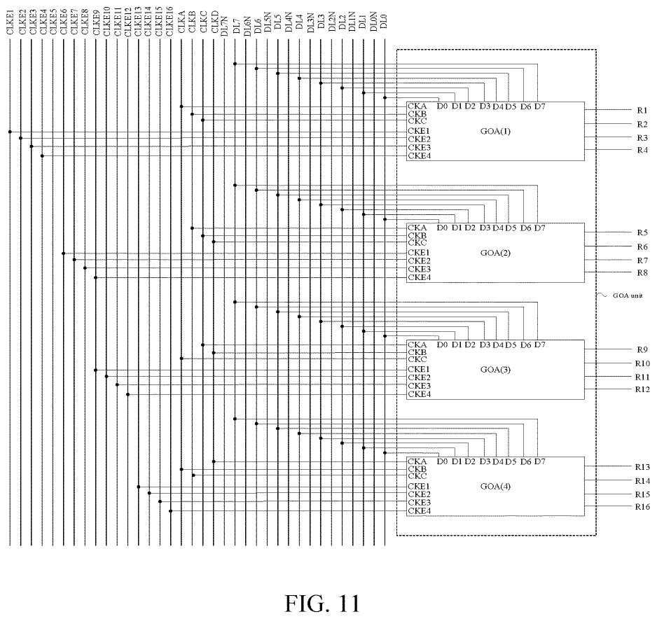

In an exemplary implementation, FIG. 11 is a schematic diagram of a connection of a plurality of shift registers. A shift register GOA includes: M gating signal terminals, and the gating signal line group includes: 2M gating signal lines. A m-th gating signal terminal is electrically connected with a (2m-1)-th gating signal line or a 2m-th gating signal line, and a signal of the (2m-1)-th gating signal line and a signal of the 2m-th gating signal line are mutually inverted signals, 1≤m≤M. Taking M=8 as an example, in conjunction with FIG. 6, FIG. 8 and FIG. 9, a first gating signal terminal D0 is electrically connected with a first gating signal line DL0 or a second gating signal line DLN0, a second gating signal terminal D1 is electrically connected with a third gating signal line DL1 or a fourth gating signal line DLN1, a third gating signal terminal D2 is electrically connected with a fifth gating signal line DL2 or a sixth gating signal line DLN2, a fourth gating signal terminal D3 is electrically connected with a seventh gating signal line DL3 or an eighth gating signal line DLN3, a fifth gating signal terminal D4 is electrically connected with a ninth gating signal line DL4 or a tenth gating signal line DLN4, a sixth gating signal terminal D5 is electrically connected with an eleventh gating signal line DL5 or a twelfth gating signal line DLN5, a seventh gating signal terminal D6 is electrically connected with a thirteenth gating signal line DL6 or a fourteenth gating signal line DLN6, and an eighth gating signal terminal D7 is electrically connected with a fifteenth gating signal line DL7 or a sixteenth gating signal line DLN7.

In an exemplary implementation, frequencies of the signals of the first gating signal terminal D0 to the eighth gating signal terminal D7 may be sequentially reduced, that is, signal pulses of the first gating signal terminal D0 to the eighth gating signal terminal D7 may be sequentially increased. Exemplarily, a signal frequency of a gating signal of the first gating signal terminal D0 is the highest, a signal frequency of a gating signal of the second gating signal terminal D1 is half of the signal frequency of the gating signal of the first gating signal terminal D0, a signal frequency of a gating signal of the third gating signal terminal D2 is half of the signal frequency of the gating signal of the second gating signal terminal D1, a signal frequency of a gating signal of the fourth gating signal terminal D3 is half of the signal frequency of the gating signal of the third gating signal terminal D2, a signal frequency of a gating signal of the fifth gating signal terminal D4 is half of the signal frequency of the gating signal of the fourth gating signal terminal D3, a signal frequency of a gating signal of the sixth gating signal terminal D5 is half of the signal frequency of the gating signal of the fifth gating signal terminal D4, a signal frequency of a gating signal of the seventh gating signal terminal D6 is half of the signal frequency of the gating signal of the sixth gating signal terminal D5, and a signal frequency of a gating signal of the eighth gating signal terminal D7 is half of the signal frequency of the gating signal of the seventh gating signal terminal D6. A signal pulse width of the gating signal of the first gating signal terminal D0 is the smallest, a signal pulse width of the gating signal of the second gating signal terminal D1 is twice the signal pulse width of the gating signal of the first gating signal terminal D0, a signal pulse width of the gating signal of the third gating signal terminal D2 is twice the signal pulse width of the gating signal of the second gating signal terminal D1, a signal pulse width of the gating signal of the fourth gating signal terminal D3 is twice the signal pulse width of the gating signal of the third gating signal terminal D2, a signal pulse width of the gating signal of the fifth gating signal terminal D4 is twice the signal pulse width of the gating signal of the fourth gating signal terminal D3, a signal pulse width of the gating signal of the sixth gating signal terminal D5 is twice the signal pulse width of the gating signal of the fifth gating signal terminal D4, a signal pulse width of the gating signal of the seventh gating signal terminal D6 is twice the signal pulse width of the gating signal of the sixth gating signal terminal D5, and a signal pulse width of the gating signal of the eighth gating signal terminal D7 is twice the signal pulse width of the gating signal of the seventh gating signal terminal D6.

In an exemplary implementation, as shown in FIGS. 8 and 9, the non-display region 200 has a signal line region and a device region, and the gate drive circuit is at least partially located in the device region. The signal line region may include a first signal line region RS1, a second signal line region RS2, and a third signal line region RS3 sequentially disposed along a direction close to the display region 100, and the device region may include a first device region RT1, a second device region RT2, a third device region RT3, and a fourth device region RT4 sequentially disposed along the direction close to the display region 100. The first signal line region RS1 is located at a side of the first device region RT1 away from the display region 100, and the third signal line region RS3 is located at a side of the fourth device region RT4 close to the display region 100.

In an exemplary implementation, as shown in FIGS. 8 and 9, the gating signal line group DL may be located in the first signal line region RS1.

In an exemplary implementation, as shown in FIGS. 8 and 9, the gating sub-circuit 10 may be located in the first device region RT1.

In an exemplary implementation, as shown in FIGS. 8 and 9, the second signal line region RS2 may be located between the first signal line region RS1 and the first device region RT1, or may be located between the first device region RT1 and the second device region RT2. FIG. 8 is illustrated by taking a case that the second signal line region RS2 may be located between the first signal line region RS1 and the first device region RT1 as an example. FIG. 9 is illustrated by taking a case that the second signal line region RS2 is located between the first device region RT1 and the second device region RT2 as an example.

In an exemplary implementation, as shown in FIGS. 8 and 9, a length of the first signal line region RS1 along the second direction D2 is greater than a length of the second signal line region RS2 along the second direction D2.

In an exemplary implementation, as shown in FIGS. 8 and 9, a length of the third signal line region RS3 along the second direction D2 is greater than the length of the second signal line region RS2 along the second direction D2.

In an exemplary implementation, as shown in FIGS. 8 and 9, the non-display region 200 is further provided with a clock signal line group CLK, and the gate drive circuit is electrically connected with the clock signal line group CLK. The clock signal line group CLK is located in the first signal line region RS1 and at a side of the gating signal line group DL away from the display region 100.

In an exemplary implementation, as shown in FIGS. 8, 9, and 11, the clock signal line group CLK includes a control clock signal line group CLK2 and an output clock signal line group CLK1. The control clock signal line group CLK2 includes a plurality of control clock signal lines, a control clock signal line extends along the first direction D1, and the plurality of control clock signal lines are arranged along the second direction D2. The output clock signal line group CLK1 includes a plurality of output clock signal lines, an output clock signal line extends along the first direction D1 and the plurality of output clock signal lines are arranged along the second direction D2. A line width of an output clock signal line is larger than a line width of a control clock signal line and a line width of a gating signal line. FIGS. 8, 9, and 11 are illustrated by taking 16 output clock signal lines and 4 control clock signal lines as an example.

In an exemplary implementation, as shown in FIG. 11, the shift register includes a plurality of control clock terminals and a plurality of output clock terminals, any one of the plurality of control clock terminals is electrically connected with one of the control clock signal lines in the control clock signal line group CLK2, and any one of the plurality of output clock terminals is electrically connected with one of the output clock signal lines in the output clock signal line group CLK1. For any shift register, the plurality of control clock terminals are electrically connected with a portion of the signal lines in the control clock signal group CLK2, and the plurality of output clock terminals are electrically connected with a portion of the signal lines in the output clock signal line group CLK1. FIG. 11 is illustrated by taking a case that the shift register includes three control clock terminals, such as the first control clock terminal CKA to the third control clock terminal CKC, and four output clock terminals, such as the first output clock terminal CKE1 to the fourth output clock terminal CKE4 as an example.

In an exemplary implementation, as shown in FIGS. 8 and 9, the output clock signal line group CLK1 may be located at a side of the control clock signal line group CLK2 away from the display region 100.

In an exemplary implementation, as shown in FIGS. 8 and 9, the non-display region 200 is further provided with a first high-level power supply line VDDL1 and a second high-level power supply line VDDL2. The shift register includes a first high-level power supply terminal and a second high-level power supply terminal. For any shift register, the first high-level power supply terminal is electrically connected with the first high-level power supply line VDDL1, and the second high-level power supply terminal is electrically connected with the second high-level power supply line VDDL2.

In an exemplary implementation, as shown in FIGS. 8 and 9, the first high-level power supply line VDDL1 and the second high-level power supply line VDDL2 may be located in the second signal line region RS2.

In an exemplary implementation, as shown in FIGS. 8 and 9, a line width of any power supply line of the first high-level power supply line VDDL1 and the second high-level power supply line VDDL2 is greater than a line width of any signal line located in the first signal line region RS1.

In an exemplary implementation, as shown in FIGS. 8 and 9, the non-display region 200 is further provided with a first low-level power supply line VGL1 and a second low-level power supply line VGL2. The shift register includes a first low-level power supply terminal and a second low-level power supply terminal. For any shift register, the first low-level power supply terminal is electrically connected with the first low-level power supply line VGL1, and the second low-level power supply terminal is electrically connected with the second low-level power supply line VGL2.

In an exemplary implementation, as shown in FIGS. 8 and 9, the first low-level power supply line VGL1 and the second low-level power supply line VGL2 are located in the third signal line region RS3, and the first low-level power supply line VGL1 is located at a side of the second low-level power supply line VGL2 away from the display region.

In an exemplary implementation, as shown in FIGS. 8 and 9, a line width of any power supply line of the first low-level power supply line VGL1 and the second low-level power supply line VGL2 is larger than a line width of any signal line located in the first signal line region RS1, and a line width of the first low-level power supply line VGL1 is less than a line width of the second low-level power supply line VGL2.

In an exemplary implementation, as shown in FIGS. 8 and 9, a length of the second device region RT2 along the second direction D2 is greater than a length of the first device region RT1 along the second direction D2, a length of the third device region RT3 along the second direction D2 is greater than or equal to the length of the second device region RT2 along the second direction D2, and a length of the fourth device region RT4 along the second direction D2 is greater than the length of the third device region RT3 along the second direction D2.

In an exemplary implementation, as shown in connection with FIGS. 6, 8, and 9, the shift register further includes an input sub-circuit 40, a node setting sub-circuit 20, and a preprocessing sub-circuit 30; the plurality of control clock terminals includes: a first control clock terminal to a third control clock terminal. The node setting sub-circuit 20 is at least electrically connected with the second high-level power supply terminal, the second low-level power supply terminal, the second control clock terminal, the third control clock terminal, the first node and the third node, respectively, and is configured to provide a signal of the second high-level power supply terminal or the second low-level power supply terminal to the first node under control of signals of the second control clock terminal, the third control clock terminal and the third node; the input sub-circuit 40 is at least electrically connected with the third control clock terminal, the third node and the fifth node, respectively, and is configured to provide a signal of the third control clock terminal to the fifth node under control of signals of the third node and the third control clock terminal; the preprocessing sub-circuit 30 is at least electrically connected with the second node, the third node, the fourth node, the first high-level power supply terminal and the first control clock terminal, respectively, and is configured to provide a signal of the first control clock terminal or the first high-level power supply terminal to the third node and the fourth node under control of signals of the second node and the first control clock terminal; the gating sub-circuit 10 is further electrically connected with the second control clock terminal and the second node, respectively, and is configured to provide a signal of the second control clock terminal to the second node under control of signals of the plurality of gating signal terminals;

In an exemplary implementation, as shown in FIGS. 8 and 9, the input sub-circuit 40, the node setting sub-circuit 20, and the preprocessing sub-circuit 30 may be located in the second device region RT2 and are arranged along the first direction D1, and the preprocessing sub-circuit 30 is located between the input sub-circuit 40 and the node setting sub-circuit 20. Locating the input sub-circuit 40, the node setting sub-circuit 20, and the preprocessing sub-circuit 30 in the second device region RT2 and arranging them along the first direction D1 may reduce a length of the gate drive circuit along the second direction, thereby achieving a narrow bezel of the display substrate.

In an exemplary implementation, the preprocessing sub-circuit 30 includes a plurality of preprocessing transistors and a preprocessing capacitor. The preprocessing capacitor may include the second capacitor C2 in FIG. 6, and the plurality of preprocessing transistors may include the eleventh transistor T11 to the fourteenth transistor T14 in FIG. 6. The preprocessing capacitor is located at a side of the plurality of preprocessing transistors close to the node setting sub-circuit 20. The preprocessing capacitor occupies a large area, which can ensure the storage capacity of the preprocessing capacitor, thereby improving the reliability of the gate drive circuit.

In an exemplary implementation, as shown in FIGS. 8 and 9, the shift register may further include a node separation sub-circuit 50. The node separation sub-circuit 50 is electrically connected with the third control clock terminal, the first high-level power supply terminal, the second low-level power supply terminal, the first node, the fifth node, the sixth node, the seventh node, the eighth node, and the ninth node, respectively, and is configured to provide a signal of the fifth node to the sixth node to the ninth node respectively under control of signals of the third control clock terminal and the first node, or to provide a signal of the first high-level power supply terminal to the fifth node under control of a signal of the sixth node.

In an exemplary implementation, as shown in FIGS. 8 and 9, the node separation sub-circuit 50 may be located in the third device region RT3.

In an exemplary implementation, the shift register further includes an output sub-circuit 60. The output sub-circuit 60 is at least electrically connected with the plurality of output clock terminals, the first low-level power supply terminal, and the plurality of signal output terminals, respectively, and is configured to output a signal of a corresponding output clock terminal or the first low-level power supply terminal to the plurality of signal output terminals.

In an exemplary implementation, as shown in FIGS. 8 and 9, the output sub-circuit 60 may be located in the fourth device region RT4.

In an exemplary implementation, the output sub-circuit 60 further includes a plurality of output capacitors arranged in an array along the first direction D1 and the second direction D2. The arrangement of the plurality of output capacitors in an array along the first direction D1 and the second direction D2 can reduce a length of the gate drive circuit along the second direction D2, thereby achieving a narrow bezel of the display substrate.

In an exemplary implementation, as shown in FIGS. 8 and 9, the shift register further includes a reset sub-circuit 80 and a noise reduction sub-circuit (not shown), and the plurality of control clock terminals includes a first control clock terminal to a third control clock terminal. The reset sub-circuit 80 is at least electrically connected with the global reset signal terminal, the third node, the fourth node, the first high-level power supply terminal and the second low-level power supply terminal, respectively, and is configured to provide an electrical connection from the second low-level power supply terminal to the third node, the fourth node and the first high-level power supply terminal under control of a signal of the global reset signal terminal; the noise reduction sub-circuit is at least electrically connected with the first node, the second node, the ninth node, the first control clock terminal, the second control clock terminal, and the second low-level power supply terminal, respectively, and is configured to provide a signal of the second control clock terminal to the second node under control of a signal of the first control clock terminal, and to provide a signal of the second low-level power supply terminal to the first node under control of a signal of the ninth node.

In an exemplary implementation, as shown in FIGS. 8 and 9, the reset sub-circuit 80 may be located in the second device region RT2, and the reset sub-circuit 80 and the preprocessing sub-circuit 30 are arranged along the second direction D2.

In an exemplary implementation, the noise reduction sub-circuit may be located in the second device region RT2, transistors in the noise reduction sub-circuit are of a small size, and a position where the noise reduction sub-circuit is placed can be any position, for example, the noise reduction sub-circuit may be placed between the reset sub-circuit 80 and the node separation sub-circuit 50, and arranged along the second direction D2 with the reset sub-circuit 80 and the node separation sub-circuit 50, or may be placed between the reset sub-circuit 80 and the node setting sub-circuit 20, and arranged along the first direction D1 with the reset sub-circuit 80 and the node setting sub-circuit 20, which is not limited in present disclosure.

In an exemplary implementation, the non-display region 200 is further provided with a reset signal line. The global reset signal terminal of the shift register is electrically connected with the reset signal line.

In an exemplary implementation, the reset signal line may be located in the first signal line region RS1.

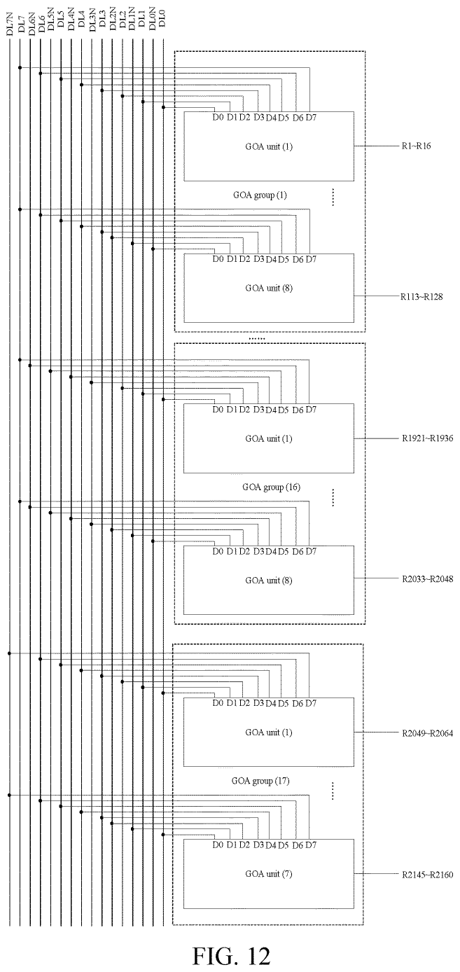

In an exemplary implementation, FIG. 12 is a schematic diagram of a connection of a plurality of shift register groups. As shown in FIGS. 11 and 12, the gate drive circuit includes a plurality of shift register groups (hereinafter referred to as GOA groups for short), a shift register group includes N1 shift register units (hereinafter referred to as GOA units for short), and a GOA unit includes N2 shift registers GOA, N1, N2≥2. FIG. 11 is illustrated by taking a case that a GOA unit includes four GOAs as an example, FIG. 11 shows a GOA unit including a first shift register GOA (1) to a fourth shift register GOA (4), each GOA is connected with four rows of sub-pixels, GOA (1) is connected with a first row of sub-pixels R1 to a fourth row of sub-pixels R4, GOA (2) is connected with a fifth row of sub-pixels R5 to an eighth row of sub-pixels R8, GOA (3) is connected with a ninth row of sub-pixels R9 to a twelfth row of sub-pixels R12, and GOA (3) is connected with a thirteenth row of sub-pixels R13 to a sixteenth row of sub-pixels T16. FIG. 12 is illustrated by taking a case in which the gate drive circuit is connected with 2160 rows of sub-pixels, and the gate drive circuit includes 17 GOA groups, such as GOA group (1) to GOA group (17) as an example.

In an exemplary implementation, as shown in FIG. 11, a portion of gating signal lines connected with a plurality of gating signal terminals of a shift register are called gating signal line units; gating signal lines included in gating signal line units connected with any two shift registers located in a same shift register unit are the same, and at least one of gating signal lines included in gating signal line units connected with any two shift register units located in a same shift register group is different; and gating signal lines included in gating signal line units connected with n1-th shift register units located in different shift register groups are the same, 1≤n1≤N1. FIG. 11 is illustrated by taking a case that for all shift registers located in a same GOA unit, first gating signal terminals D0 are electrically connected with a first gating signal line DL0, second gating signal terminals D1 are electrically connected with a third gating signal line DL1, third gating signal terminals D2 are electrically connected with a fifth gating signal line DL2, fourth gating signal terminals D3 are electrically connected with a seventh gating signal line DL3, fifth gating signal terminals D4 are electrically connected with a ninth gating signal line DL4, sixth gating signal terminals D5 are electrically connected with an eleventh gating signal line DL5, seventh gating signal terminals D6 are electrically connected with a thirteenth gating signal line DL6, and eighth gating signal terminals D7 are electrically connected with a fifteenth gating signal line DL7 as an example. FIG. 12 is illustrated by taking a case that for all shift registers in a GOA unit (1) of a first GOA group, first gating signal terminals D0 are electrically connected with a first gating signal line DL0, second gating signal terminals D1 are electrically connected with a third gating signal line DL1, third gating signal terminals D2 are electrically connected with a fifth gating signal line DL2, fourth gating signal terminals D3 are electrically connected with a seventh gating signal line DL3, fifth gating signal terminals D4 are electrically connected with a ninth gating signal line DL4, sixth gating signal terminals D5 are electrically connected with a eleventh gating signal line DL5, seventh gating signal terminals D6 are electrically connected with a thirteenth gating signal line DL6, and eighth gating signal terminals D7 are electrically connected with a fifteenth gating signal line DL7, and for a GOA unit (8), first gating signal terminals D0 are electrically connected with a second gating signal line DLN0, second gating signal terminals D1 are electrically connected with a fourth gating signal line DLN1, third gating signal terminals D2 are electrically connected with a sixth gating signal line DLN2, fourth gating signal terminals D3 are electrically connected with a seventh gating signal line DL3, fifth gating signal terminals D4 are electrically connected with a ninth gating signal line DL4, sixth gating signal terminals D5 are electrically connected with a eleventh gating signal line DL5, seventh gating signal terminals D6 are electrically connected with a thirteenth gating signal line DL6, and eighth gating signal terminals D7 are electrically connected with a fifteenth gating signal line DL7 as an example. The present disclosure is not limited in this regard.

In an exemplary implementation, a portion of control clock signal lines connected with a plurality of control clock terminals of a shift register are called control clock signal line units, and a portion of output clock signal lines connected with a plurality of output clock terminals of a shift register are called output clock signal line units; at least one of control clock signal lines included in control clock signal line units connected with any two shift registers located in a same shift register unit are different, and at least one of output clock signal lines included in output clock signal line units connected with any two shift registers located in a same shift register unit are different; control clock signal lines included in control clock signal line units connected with n2-th shift registers located in different shift register units are the same, and output clock signal lines included in output clock signal line units connected with n2-th shift registers located in different shift register units are the same, 1≤n2≤N2. In an exemplary implementation, FIG. 11 is illustrated by taking a case in which for GOA (1), a first control clock terminal CKA is electrically connected with a first control clock signal line CLKA, a second control clock terminal CKB is electrically connected with a second control clock signal line CLKB, a third control clock terminal CKC is electrically connected with a third control clock signal line CLKC, a first output clock terminal CKE1 is electrically connected with a first output clock signal line CLKE1, a second output clock terminal CKE2 is electrically connected with a second output clock signal line CLKE2, a third output clock terminal CKE3 is electrically connected with a third output clock signal line CLKE3, a fourth output clock terminal CKE4 is electrically connected with a fourth output clock signal line CLKE4, for GOA (2), a first control clock terminal CKA is electrically connected with the second control clock signal line CLKB, a second control clock terminal CKB is electrically connected with the third control clock signal line CLKC, a third control clock terminal CKC is electrically connected with a fourth control clock signal line CLKD, a first output clock terminal CKE1 is electrically connected with a fifth output clock signal line CLKE5, a second output clock terminal CKE2 is electrically connected with a sixth output clock signal line CLKE6, a third output clock terminal CKE3 is electrically connected with a seventh output clock signal line CLKE7, a fourth output clock terminal CKE4 is electrically connected with an eighth output clock signal line CLKE8, for GOA (3), a first control clock terminal CKA is electrically connected with the third control clock signal line CLKC, a second control clock terminal CKB is electrically connected with the fourth control clock signal line CLKD, a third control clock terminal CKC is electrically connected with the first control clock signal line CLKA, a first output clock terminal CKE1 is electrically connected with a ninth output clock signal line CLKE9, a second output clock terminal CKE2 is electrically connected with a tenth output clock signal line CLKE10, a third output clock terminal CKE3 is electrically connected with an eleventh output clock signal line CLKE11, a fourth output clock terminal CKE4 is electrically connected with a twelfth output clock signal line CLKE12, and for GOA (4), a first control clock terminal CKA is electrically connected with the fourth control clock signal line CLKD, a second control clock terminal CKB is electrically connected with the first control clock signal line CLKA, a third control clock terminal CKC is electrically connected with the second control clock signal line CLKB, a first output clock terminal CKE1 is electrically connected with a thirteenth output clock signal line CLKE13, a second output clock terminal CKE2 is electrically connected with a fourteenth output clock signal line CLKE14, a third output clock terminal CKE3 is electrically connected with a fifteenth output clock signal line CLKE15, a fourth output clock terminal CKE4 is electrically connected with a sixteenth output clock signal line CLKE16 as an example.

In an exemplary implementation, a quantity of shift registers included in a shift register unit can be determined in accordance with a quantity of combinations of gating signals available for access. If one shift register has two gating signal ports, the shift register is accessed with two gating signals. There are four gating signals available for access, two of which are mutually inverted signals, and the other two are mutually inverted signals, then the four gating signals can form four combinations for accessing shift registers, so that four shift register groups can be formed, and each shift register in each shift register group is accessed with the same combination of gating signals.

In an exemplary implementation, a quantity of shift registers included in a shift register unit may be determined in accordance with a quantity of clock signals provided.

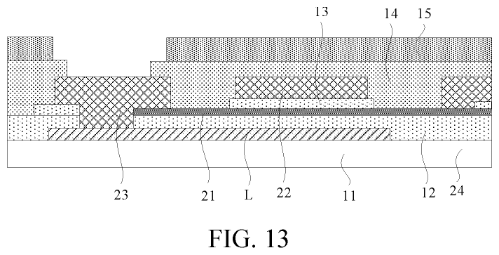

In an exemplary implementation, FIG. 13 is a sectional schematic diagram of a display substrate. As shown in FIG. 13, the display substrate includes a base substrate 11 and a drive structure layer provided on the base substrate, and the shift register includes a plurality of transistors. The drive structure layer includes a first conductive layer, a first insulating layer 12, a semiconductor layer, a second insulating layer 13, and a second conductive layer which are stacked on the base substrate. FIG. 13 shows only one of the transistors. The transistor includes an active pattern 21, a gate electrode 22, a first electrode 23, and a second electrode 24.

In an exemplary implementation, the semiconductor layer at least includes active patterns of the plurality of transistors in the shift register.

In an exemplary implementation, the second conductive layer at least includes gate electrodes, first electrodes, and second electrodes of the plurality of transistors in the shift register.

In an exemplary implementation, the drive structure layer may further include a third insulating layer 14 and a planarization layer 15.

In an exemplary implementation, the first conductive layer at least includes a signal line L to which the transistors are connected. The signal line L may be any of a gating signal line, a control clock signal line, an output clock signal line, a first high-level power supply line VDDL1, a second high-level power supply line VDDL2, a first low-level power supply line VGL1, and a second low-level power supply line VGL2.

In an exemplary implementation, any one of the gating signal line, the control clock signal line, the output clock signal line, the first high-level power supply line VDDL1, the second high-level power supply line VDDL2, the first low-level power supply line VGL1, and the second low-level power supply line VGL2 is of a single-layer structure and is located in the first conductive layer, or is of a double-layer structure, and is located in the first conductive layer and the second conductive layer.

In an exemplary implementation, as shown in FIG. 10, the non-display region is further provided with a first connection line L1 and a second connection line L2, and the first connection line L1 and the second connection line L2 may be located in the first conductive layer.

In an exemplary implementation, as shown in FIG. 10, first electrodes of all gating transistors located in a same gating sub-circuit are electrically connected with the first connection line L1, and second electrodes of a plurality of gating transistors located in a same gating sub-circuit are electrically connected with the second connection line L2.

In an exemplary implementation, as shown in FIG. 10, any one of a gate electrode, a first electrode, and a second electrode in any gating transistor extends at least partially along the second direction D2, and the first connection line L1 and the second connection line L2 extend along the first direction D1.

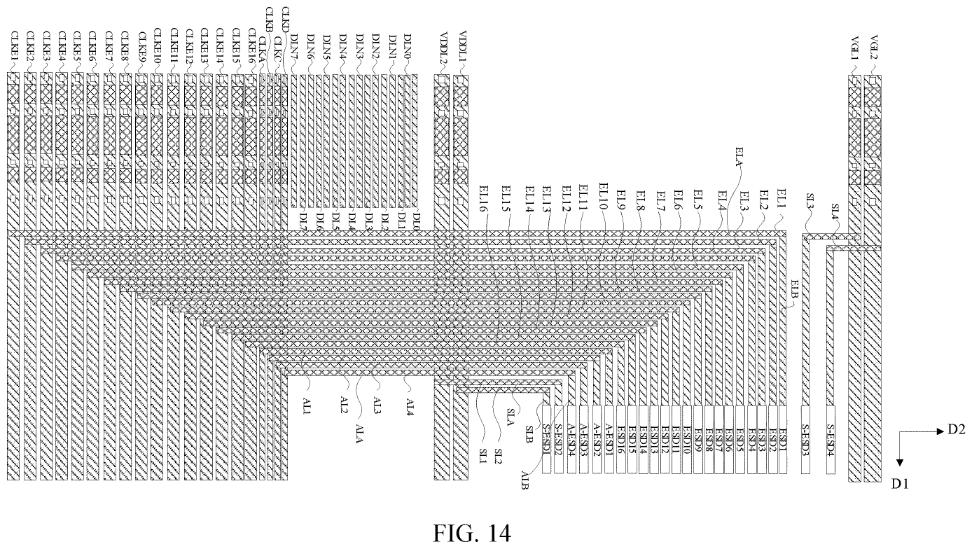

In an exemplary implementation, FIG. 14 is a partial schematic view of a non-display region of a display substrate. As shown in FIG. 14, the non-display region 200 is further provided with a plurality of control clock connection lines and a plurality of control clock electrostatic release circuits; the plurality of control clock connection lines are in one-to-one correspondence with the plurality of control clock signal lines, and the plurality of control clock connection lines are in one-to-one correspondence with the plurality of control clock electrostatic release circuits. FIG. 14 is illustrated by taking a case that the plurality of control clock connection lines include a first control clock connection line AL1 to a fourth control clock connection line ALA, and the plurality of control clock electrostatic release circuits include a first control clock electrostatic release circuit A-ESD1 to a fourth control clock electrostatic release circuit A-ESD4 as an example. The first control clock connection line AL1 corresponds to the first control clock signal line CLKA, the second control clock connection line AL2 corresponds to the second control clock signal line CLKB, the third control clock connection line AL3 corresponds to the third control clock signal line CLKC, the fourth control clock connection line ALA corresponds to the fourth control clock signal line CLKD, the first control clock connection line AL1 corresponds to the first control clock electrostatic release circuit A-ESD1, the second control clock connection line AL2 corresponds to the second control clock electrostatic release circuit A-ESD2, the third control clock connection line AL3 corresponds to the third control clock electrostatic release circuit A-ESD3, and the fourth control clock connection line ALA corresponds to the fourth control clock electrostatic release circuit A-ESD4.

In an exemplary implementation, as shown in FIG. 14, a control clock connection line is electrically connected with a corresponding control clock signal line and a corresponding control clock electrostatic release circuit, respectively. Exemplarily, the first control clock connection line AL1 is electrically connected with the first control clock signal line CLKA and the first control clock electrostatic release circuit A-ESD1, the second control clock connection line AL2 is electrically connected with the second control clock signal line CLKB and the second control clock electrostatic release circuit A-ESD2, the third control clock connection line AL3 is electrically connected with the third control clock signal line CLKC and the third control clock electrostatic release circuit A-ESD3, and the fourth control clock connection line ALA is electrically connected with the fourth control clock signal line CLKD and the fourth control clock electrostatic release circuit A-ESD4, respectively.

In an exemplary implementation, as shown in FIG. 14, a control clock connection line includes a first control clock connection part ALA extending along the second direction D2 and a second control clock connection part ALB extending along the first direction D1. For any control clock connection line, the first control clock connection part ALA is electrically connected with a corresponding control clock signal line and the second control clock connection part ALB, respectively, and the second control clock connection part is electrically connected with a corresponding control clock electrostatic release circuit. Exemplarily, the first control clock connection part ALA of the first control clock connection line ALI is electrically connected with the first control clock signal line CLKA and the second control clock connection part ALB of the first control clock connection line AL1, respectively, and the second control clock connection part ALB of the first control clock connection line AL1 is electrically connected with the first control clock electrostatic release circuit A-ESD1. The first control clock connection part ALA of the second control clock connection line AL2 is electrically connected with the second control clock signal line CLKB and the second control clock connection part ALB of the second control clock connection line AL2, respectively, the second control clock connection part ALB of the second control clock connection line AL2 is electrically connected with the second control clock electrostatic release circuit A-ESD2, the first control clock connection part ALA of the third control clock connection line AL3 is electrically connected with the third control clock signal line CLKC and the second control clock connection part ALB of the third control clock connection line AL3, respectively, and the second control clock connection part ALB of the third control clock connection line AL3 is electrically connected with the third control clock electrostatic release circuit A-ESD3. The first control clock connection part ALA of the fourth control clock connection line AL4 is electrically connected with the fourth control clock signal line CLKD and the second control clock connection part ALB of the fourth control clock connection line ALA, respectively, and the second control clock connection part ALB of the fourth control clock connection line AL4 is electrically connected with the fourth control clock electrostatic release circuit A-ESD4.

In an exemplary implementation, as shown in FIG. 14, first control clock connection parts ALA are located in the second conductive layer, and second control clock connection parts ALB are located in the first conductive layer.

In an exemplary implementation, as shown in FIG. 14, the non-display region 200 is further provided with a plurality of output clock connection lines and a plurality of output clock electrostatic release circuits; the plurality of output clock connection lines are in one-to-one correspondence with the plurality of output clock signal lines, and the plurality of output clock connection lines are in one-to-one correspondence with the plurality of output clock electrostatic release circuits. FIG. 14 is illustrated by taking a case that the plurality of output clock connection lines include a first output clock connection line EL1 to a sixteenth output clock connection line EL16, and the plurality of output clock electrostatic release circuits include a first output clock electrostatic release circuit ESD1 to a sixteenth output clock electrostatic release circuit ESD16 as an example. The first output clock connection line EL1 corresponds to the first output clock signal line CLKE1, the second output clock connection line EL2 corresponds to the second output clock signal line CLKE2, the third output clock connection line EL3 corresponds to the third output clock signal line CLKE3, the fourth output clock connection line EL4 corresponds to the fourth output clock signal line CLKE4, and so on, the first output clock connection line EL1 corresponds to the first output clock electrostatic release circuit ESD1, the second output clock connection line EL2 corresponds to the second output clock electrostatic release circuit ESD2, the third output clock connection line EL3 corresponds to the third output clock electrostatic release circuit ESD3, and the fourth output clock connection line ELA corresponds to the fourth output clock electrostatic release circuit ESD4, and so on.

In an exemplary implementation, as shown in FIG. 14, an output clock connection line is electrically connected with a corresponding output clock signal line and a corresponding output clock electrostatic release circuit, respectively. The first output clock connection line EL1 is electrically connected with the first output clock signal line CLKE1 and the first output clock electrostatic release circuit ESD1, respectively, the second output clock connection line EL2 is electrically connected with the second output clock signal line CLKE2 and the second output clock electrostatic release circuit ESD2, the third output clock connection line EL3 is electrically connected with the third output clock signal line CLKE3 and the third output clock electrostatic release circuit ESD3, the fourth output clock connection line EL4 is electrically connected with the fourth output clock signal line CLKE4 and the fourth output clock electrostatic release circuit ESD4, and so on.

In an exemplary implementation, as shown in FIG. 14, an output clock connection line includes a first output clock connection part ELA extending along the second direction D2 and a second output clock connection part ELB extending along the first direction D1. For any output clock connection line, the first output clock connection part is electrically connected with a corresponding output clock signal line and the second output clock connection part, and the second output clock connection part is electrically connected with a corresponding output clock electrostatic release circuit. Exemplarily, the first output clock connection part ELA of the first output clock connection line EL1 is electrically connected with the first output clock signal line CLKE1 and the second output clock connection part ELB of the first output clock connection line EL1, respectively, the second output clock connection part ELB of the first output clock connection line EL1 is electrically connected with the first output clock electrostatic release circuit ESD1, the first output clock connection part ELA of the second output clock connection line EL2 is electrically connected with the second output clock signal line CLKE2 and the second output clock connection part ELB of the second output clock connection line EL2, respectively, the second output clock connection part ELB of the second output clock connection line EL2 is electrically connected with the second output clock electrostatic release circuit ESD2, the first output clock connection part ELA of the third output clock connection line EL3 is electrically connected with the third output clock signal line CLKE3 and the second output clock connection part ELB of the third output clock connection line EL3, respectively, the second output clock connection part ELB of the third output clock connection line EL3 is electrically connected with the third output clock electrostatic release circuit ESD3, the first output clock connection part ELA of the fourth output clock connection line EL4 is electrically connected with the fourth output clock signal line CLKE4 and the second output clock connection part ELB of the fourth output clock connection line EL4, respectively, the second output clock connection part ELB of the fourth output clock connection line ELA is electrically connected with the fourth output clock electrostatic release circuit ESD4, and so on.

In an exemplary implementation, as shown in FIG. 14, first output clock connection parts ELA may be located in the second conductive layer, and second output clock connection parts ELB may be located in the first conductive layer.

In an exemplary implementation, as shown in FIG. 14, the non-display region 200 is further provided with four power supply connection lines and four power supply electrostatic release circuits. A first power supply connection line SL1 is electrically connected with the first high-level power supply line VDDL1 and a first power supply electrostatic release circuit S-ESD1, respectively; a second power supply connection line SL2 is electrically connected with the second high-level power supply line VDDL2 and a second power supply electrostatic release circuit S-ESD2, respectively; a third power supply connection line SL3 is electrically connected with the first low-level power supply line VGL1 and a third power supply electrostatic release circuit S-ESD3, respectively; a fourth power supply connection line SL4 is electrically connected with the second low-level power supply line VGL2 and a fourth power supply electrostatic release circuit S-ESD4, respectively.

In an exemplary implementation, as shown in FIG. 14, a power supply connection line includes a first power supply connection part SLA extending along the second direction D2 and a second power supply connection part SLB extending along the first direction D1.

In an exemplary implementation, as shown in FIG. 14, for any power supply connection line, the first power supply connection part SLA is electrically connected with a connected power supply line and the second power supply connection part SLB, respectively, and the second power supply connection part SLB is electrically connected with a connected power supply electrostatic release circuit. Exemplarily, the first power supply connection part SLA of the first power supply connection line SL1 is electrically connected with the first high-level power supply line VDDL1 and the second power supply connection part SLB of the first power supply connection line SL1, respectively, the second power supply connection part SLB of the first power supply connection line SL1 is electrically connected with the first power supply electrostatic release circuit S-ESD1, the first power supply connection part SLA of the second power supply connection line SL2 is electrically connected with the second high-level power supply line VDDL2 and the second power supply connection part SLB of the second power supply connection line SL2, respectively, the second power supply connection part SLB of the second power supply connection line SL2 is electrically connected with the second power supply electrostatic release circuit S-ESD2, the first power supply connection part SLA of the third power supply connection line SL3 is electrically connected with the first low-level power supply line VGL1 and the second power supply connection part SLB of the third power supply connection line SL3, respectively, the second power supply connection part SLB of the third power supply connection line SL3 is electrically connected with the third power supply electrostatic release circuit S-ESD3, the first power supply connection part SLA of the fourth power supply connection line SL4 is electrically connected with the second low-level power supply line VGL2 and the second power supply connection part SLB of the fourth power supply connection line SL4, respectively, and the second power supply connection part SLB of the fourth power supply connection line SLA is electrically connected with the fourth power supply electrostatic release circuit S-ESD4.

In an exemplary implementation, as shown in FIG. 14, the first power supply connection part SLA may be located in the second conductive layer, and the second power supply connection part SLB may be located in the first conductive layer.

In an exemplary implementation, as shown in FIGS. 8 and 9, a distance H between a boundary of a first signal line away from the display region and a boundary of a second signal line close to the display region is about 3,400 microns to 3,450 microns. The first signal line is a signal line in the first signal line region RS1 that is farthest from a boundary of the display region, as shown in FIGS. 8 and 9, the first signal line is the first output clock signal line CLKE1, and the second signal line is a signal line in the third signal line region RS3 that is closest to the boundary of the display region, as shown in FIGS. 8 and 9, the second signal line is the second low-level power supply line VGL2.

Exemplarily, a distance H between a boundary of the first signal line away from the display region and a boundary of the second signal line close to the display region is about 3430 microns.

In an exemplary implementation, the display substrate according to the present disclosure may be applied to a display apparatus with a pixel drive circuit, such as an OLED, a quantum dot display (QLED), a light emitting diode display (Micro LED or Mini LED), or a Quantum Dot Light Emitting Diode display (QDLED), which is not limited here in the present disclosure.

In an exemplary implementation, the display substrate may further include a light emitting structure layer located on a side of the drive structure layer away from the base substrate. The light emitting structure layer may include an anode, a pixel definition layer, an organic emitting layer, and a cathode, wherein the anode is connected with one of transistors in the drive structure layer through a via, the organic emitting layer is connected with the anode, the cathode is connected with the organic emitting layer, and the organic emitting layer emits light of corresponding color under drive of the anode and the cathode.

In an exemplary implementation, the organic emitting layer may include an Emitting Layer (EML), and any one or more of following: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary implementation, one or more of hole injection layers, hole transport layers, electron block layers, hole block layers, electron transport layers and electron injection layers of all sub-pixels may be connected together to form a common connected layer. The emitting layers of adjacent sub-pixels may overlap slightly with each other, or may be isolated from each other.

In an exemplary implementation, the display substrate may further include an encapsulation structure layer located on a side of the light emitting structure layer away from the base substrate. The encapsulation structure layer may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is disposed between the first encapsulation layer and the third encapsulation layer, which may ensure that external water vapor cannot enter the light emitting structure layer.

In an exemplary implementation, the display substrate may further include a touch structure layer located on a side of the encapsulation structure layer away from the base substrate. The touch structure layer may include a first touch insulating layer disposed on the encapsulation structure layer, a first touch metal layer disposed on the first touch insulating layer, a second touch insulating layer covering the first touch metal layer, a second touch metal layer disposed on the second touch insulating layer, and a touch protective layer covering the second touch metal layer, the first touch metal layer may include a plurality of bridge electrodes, the second touch metal layer may include a plurality of first touch electrodes and second touch electrodes, and a first touch electrode or second touch electrode may be connected with a bridge electrode through a via.

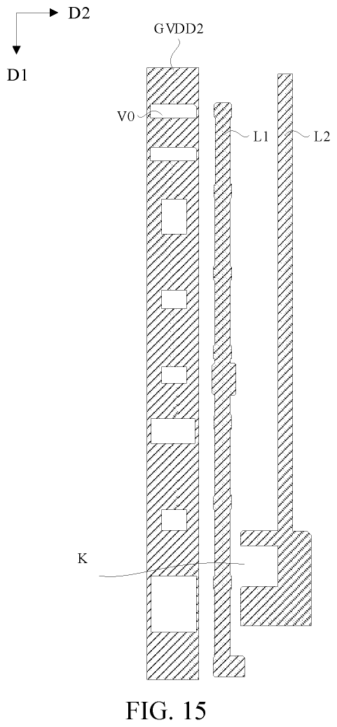

Exemplary description is made below through a preparation process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are arranged in a same layer” in the present disclosure means that A and B are formed simultaneously through a same patterning process, and a “thickness” of a film layer is a dimension of the film layer in a direction perpendicular to a display substrate. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.
(1) A pattern of a first conductive layer is formed. In an exemplary implementation, forming the pattern of the first conductive layer may include depositing a first conductive thin film on a base substrate, patterning the first conductive thin film by a patterning process to form the pattern of the first conductive layer, as shown in FIG. 15, and FIG. 15 is a schematic diagram of a pattern of a first conductive layer in FIG. 10.

In an exemplary implementation, as shown in FIG. 15, the pattern of the first conductive layer may at least include a second high-level power supply line GVDD2, a first connection line L1 and a second connection line L2 located in each shift register.

In an exemplary implementation, as shown in FIG. 15, the second high-level power supply line GVDD2 is located at a side of the first connection line L1 away from the display region, and the second connection line L2 is located at a side of the first connection line L1 close to the display region.

In an exemplary implementation, as shown in FIG. 15, the second high-level power supply line GVDD2 may be in a shape of a line with a main body portion extending along the first direction D1. The second high-level power supply line GVDD2 is provided with a via VO, which can reduce the coupling capacitance in the gate drive circuit and improve the reliability of the gate drive circuit.

In an exemplary implementation, as shown in FIG. 15, the first connection line L1 may be in a shape of a line with a main body portion extending along the first direction D1.

In an exemplary implementation, as shown in FIG. 15, the second connection line L2 may be in a shape of a line with a main body portion extending along the first direction D1. A groove K is provided on a side of the second connection line L2 close to the first connection line L1.

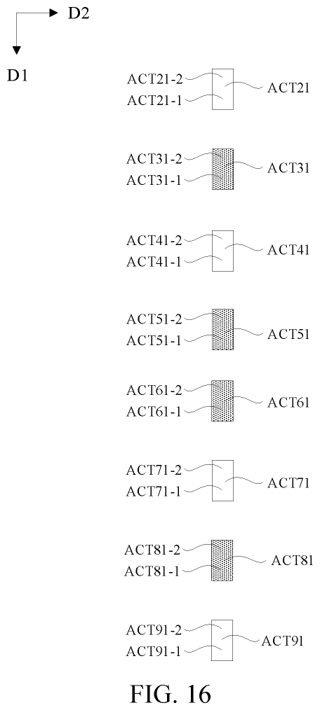

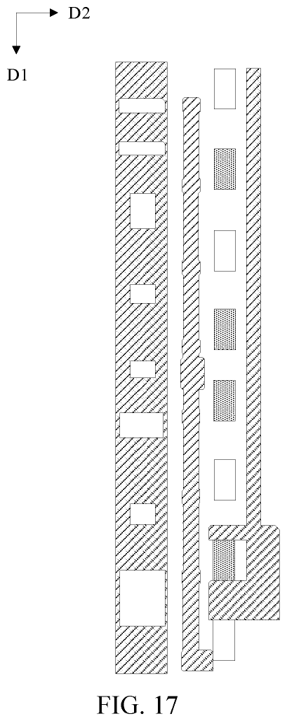

In an exemplary implementation, the first connection lines L1 and the second connection lines L2 may be in a design of equal width, or may be in a design of non-equal widths, may be straight lines, or may be bend lines, which may not only facilitate the layout of the shift register, but also reduce the parasitic capacitance between the signal lines, which is not limited here in the present disclosure.
(2) A pattern of a semiconductor layer is formed. In an exemplary implementation, forming the pattern of the semiconductor layer may include: depositing sequentially a first insulation thin film and a semiconductor thin film on the base substrate, and patterning the semiconductor thin film through a patterning process to forming a first insulating layer covering the first conductive layer, and the pattern of the semiconductor layer disposed on the first insulating layer, as shown in FIGS. 16 and 17, FIG. 16 is a schematic view of a pattern of a semiconductor layer in FIG. 10 and FIG. 17 is a schematic diagram after a pattern of a semiconductor is formed in FIG. 10.

In an exemplary implementation, as shown in FIGS. 16 and 17, the pattern of the semiconductor layer may at least include an active pattern ACT21 of the second transistor to an active pattern ACT91 of the ninth transistor located in each shift register.

In an exemplary implementation, orthographic projections of the active pattern ACT21 of the second transistor to the active pattern ACT91 of the ninth transistor on the base substrate is located between an orthographic projection of the first connection line L1 on the base substrate and an orthographic projection of the second connection line L2 on the base substrate.

In an exemplary implementation, the active pattern ACT21 of the second transistor to the active pattern ACT91 of the ninth transistor are individually provided and are sequentially arranged along the first direction D1.

In an exemplary implementation, any active pattern of the active pattern ACT21 of the second transistor to the active pattern ACT91 of the ninth transistor extends along the first direction D1.

In an exemplary implementation, an active pattern ACT81 of the eighth transistor is located within the groove of the first connection line.

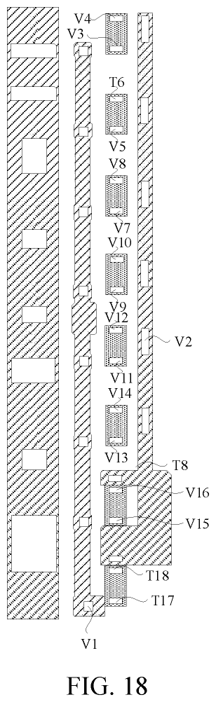

In an exemplary implementation, an active pattern of each transistor may include a first region, a second region, and a channel region located between the first region and the second region. In an exemplary implementation, the first region ACT21-1 and the second region ACT21-2 of the active pattern ACT21 of the second transistor, the first region ACT31-1 and the second region ACT31-2 of the active pattern ACT31 of the third transistor, the first region ACT41-1 and the second region ACT41-2 of the active pattern ACT41 of the fourth transistor, the first region ACT51-1 and the second region ACT51-2 of the active pattern ACT51 of the fifth transistor, the first region ACT61-1 and the second region ACT61-2 of the active pattern ACT61 of the sixth transistor, the first region ACT71-1 and the second region ACT71-2 of the active pattern ACT71 of the seventh transistor, the first region ACT81-1 and the second region ACT81-2 of the active pattern ACT81 of the eighth transistor, and the first region ACT91-1 and the second region ACT91-2 of the active pattern ACT91 of the ninth transistor are individually provided.
(3) A pattern of a second insulating layer is formed. In an exemplary implementation, forming the pattern of the second insulating layer may include depositing a second insulating thin film on the base substrate on which the above-mentioned patterns are formed, patterning the second insulating thin film using a patterning process to form a second insulating layer covering the pattern of the semiconductor layer, a plurality of vias provided on the second insulating layer, as shown in FIG. 18, and FIG. 18 is a schematic diagram after a pattern of a second insulating layer is formed in FIG. 10.

In an exemplary implementation, as shown in FIG. 18, the plurality of vias of the pattern of the second insulating layer at least include a first via V1 to an eighteenth via V18 located in the shift register.

In an exemplary implementation, an orthographic projection of the first via V1 on the base substrate is within a range of an orthographic projection of the first connection line on the base substrate, the first insulating layer and the second insulating layer within the first via V1 are etched away to expose a surface of the first connection line, and the first via V1 is configured such that a first electrode of the subsequently formed second transistor to a first electrode of the subsequently formed ninth transistor are connected with the first connection line through the via.

In an exemplary implementation, an orthographic projection of the second via V2 on the base substrate is within a range of an orthographic projection of the second connection line on the base substrate, the first insulating layer and the second insulating layer within the second via V2 are etched away to expose a surface of the second connection line, and the second via V2 is configured such that a second electrode of the subsequently formed second transistor to a second electrode of the subsequently formed ninth transistor are connected with the second connection line through the via.

In an exemplary implementation, an orthographic projection of the third via V3 on the base substrate is within a range of an orthographic projection of a first region of the active pattern of the second transistor on the base substrate, the third via V3 exposes a surface of the first region of the active pattern of the second transistor, and the third via V3 is configured such that a first electrode of the subsequently formed second transistor is connected with the first region of the active pattern of the second transistor through the via.

In an exemplary implementation, an orthographic projection of the fourth via V4 on the base substrate is within a range of an orthographic projection of a second region of the active pattern of the second transistor on the base substrate, the fourth via V4 exposes a surface of the second region of the active pattern of the second transistor, and the fourth via V4 is configured such that a second electrode of the subsequently formed second transistor is connected with the second region of the active pattern of the second transistor through the via.

In an exemplary implementation, an orthographic projection of the fifth via V5 on the base substrate is within a range of an orthographic projection of a first region of the active pattern of the third transistor on the base substrate, the fifth via V5 exposes a surface of the first region of the active pattern of the third transistor, and the fifth via V5 is configured such that a first electrode of the subsequently formed third transistor is connected with the first region of the active pattern of the third transistor through the via.

In an exemplary implementation, an orthographic projection of the sixth via V6 on the base substrate is within a range of an orthographic projection of a second region of the active pattern of the third transistor on the base substrate, the sixth via V6 exposes a surface of the second region of the active pattern of the third transistor, and the sixth via V6 is configured such that a second electrode of the subsequently formed third transistor is connected with the second region of the active pattern of the third transistor through the via.

In an exemplary implementation, an orthographic projection of the seventh via V7 on the base substrate is within a range of an orthographic projection of a first region of the active pattern of the fourth transistor on the base substrate, the seventh via V7 exposes a surface of the first region of the active pattern of the fourth transistor, and the seventh via V7 is configured such that a first electrode of the subsequently formed fourth transistor is connected with the first region of the active pattern of the fourth transistor through the via.

In an exemplary implementation, an orthographic projection of the eighth via V8 on the base substrate is within a range of an orthographic projection of a second region of the active pattern of the fourth transistor on the base substrate, the eighth via V8 exposes a surface of the second region of the active pattern of the fourth transistor, and the eighth via V8 is configured such that a second electrode of the subsequently formed fourth transistor is connected with the second region of the active pattern of the fourth transistor through the via.

In an exemplary implementation, an orthographic projection of the ninth via V9 on the base substrate is within a range of an orthographic projection of a first region of the active pattern of the fifth transistor on the base substrate, the ninth via V9 exposes a surface of the first region of the active pattern of the fifth transistor, and the ninth via V9 is configured such that a first electrode of the subsequently formed fifth transistor is connected with the first region of the active pattern of the fifth transistor through the via.

In an exemplary implementation, an orthographic projection of the tenth via V10 on the base substrate is within a range of an orthographic projection of a second region of the active pattern of the fifth transistor on the base substrate, the tenth via V10 exposes a surface of the second region of the active pattern of the fifth transistor, and the tenth via V10 is configured such that a second electrode of the subsequently formed fifth transistor is connected with the second region of the active pattern of the fifth transistor through the via.

In an exemplary implementation, an orthographic projection of the eleventh via V11 on the base substrate is within a range of an orthographic projection of a first region of the active pattern of the sixth transistor on the base substrate, the eleventh via V11 exposes a surface of the first region of the active pattern of the sixth transistor, and the eleventh via V11 is configured such that a first electrode of the subsequently formed sixth transistor is connected with the first region of the active pattern of the sixth transistor through the via.

In an exemplary implementation, an orthographic projection of the twelfth via V12 on the base substrate is within a range of an orthographic projection of a second region of the active pattern of the sixth transistor on the base substrate, the twelfth via V12 exposes a surface of the second region of the active pattern of the sixth transistor, and the twelfth via V12 is configured such that a second electrode of the subsequently formed sixth transistor is connected with the second region of the active pattern of the sixth transistor through the via.

In an exemplary implementation, an orthographic projection of the thirteenth via V13 on the base substrate is within a range of an orthographic projection of a first region of the active pattern of the seventh transistor on the base substrate, the thirteenth via V13 exposes a surface of the first region of the active pattern of the seventh transistor, and the thirteenth via V13 is configured such that a first electrode of the subsequently formed seventh transistor is connected with the first region of the active pattern of the seventh transistor through the via.

In an exemplary implementation, an orthographic projection of the fourteenth via V14 on the base substrate is within a range of an orthographic projection of a second region of the active pattern of the seventh transistor on the base substrate, the fourteenth via V14 exposes a surface of the second region of the active pattern of the seventh transistor, and the fourteenth via V14 is configured such that a second electrode of the subsequently formed seventh transistor is connected with the second region of the active pattern of the seventh transistor through the via.

In an exemplary implementation, an orthographic projection of the fifteenth via V15 on the base substrate is within a range of an orthographic projection of a first region of the active pattern of the eighth transistor on the base substrate, the fifteenth via V15 exposes a surface of the first region of the active pattern of the eighth transistor, and the fifteenth via V15 is configured such that a first electrode of the subsequently formed eighth transistor is connected with the first region of the active pattern of the eighth transistor through the via.

In an exemplary implementation, an orthographic projection of the sixteenth via V16 on the base substrate is within a range of an orthographic projection of a second region of the active pattern of the eighth transistor on the base substrate, the sixteenth via V16 exposes a surface of the second region of the active pattern of the eighth transistor, and the sixteenth via V16 is configured such that a second electrode of the subsequently formed eighth transistor is connected with the second region of the active pattern of the eighth transistor through the via.

In an exemplary implementation, an orthographic projection of the seventeenth via V17 on the base substrate is within a range of an orthographic projection of a first region of the active pattern of the ninth transistor on the base substrate, the seventeenth via V17 exposes a surface of the first region of the active pattern of the ninth transistor, and the seventeenth via V17 is configured such that a first electrode of the subsequently formed ninth transistor is connected with the first region of the active pattern of the ninth transistor through the via.

In an exemplary implementation, an orthographic projection of the eighteenth via V18 on the base substrate is within a range of an orthographic projection of a second region of the active pattern of the ninth transistor on the base substrate, the eighteenth via V18 exposes a surface of the second region of the active pattern of the ninth transistor, and the eighteenth via V18 is configured such that a second electrode of the subsequently formed ninth transistor is connected with the second region of the active pattern of the ninth transistor through the via.

In an exemplary implementation, as shown in FIG. 18, the quantity of the first via V1 is multiple and multiple first vias are arranged along the first direction D1. The quantity of the second via V2 is multiple, and at least a portion of the second vias V2 are arranged along the first direction D1. A portion of the second vias are arranged along the first direction D1 with the fifteenth via and the sixteenth via.

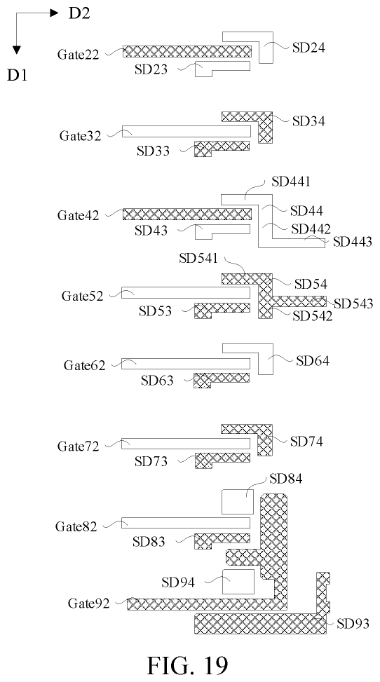

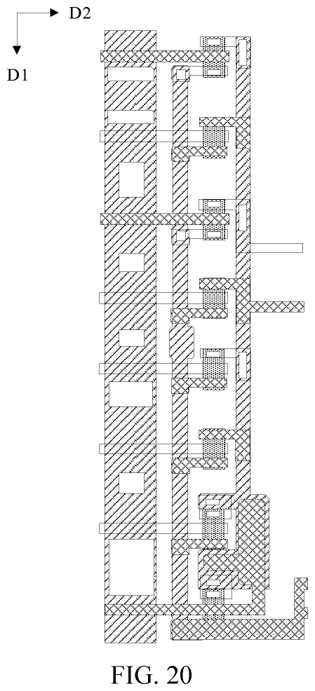

In an exemplary implementation, as shown in FIG. 18, the third through V3 to the eighteenth through V18 are arranged along the first direction D1, and the quantity of any of the third through V3 to the eighteenth through V18 may be one.
(4) A pattern of a second conductive layer is formed. In an exemplary implementation, forming the pattern of the second conductive layer may include depositing a second conductive thin film on the base substrate, patterning the second conductive thin film by a patterning process to form the pattern of the second conductive layer, as shown in FIGS. 19 and 20, FIG. 19 is a schematic diagram of a pattern of a second conductive layer in FIG. 10, and FIG. 20 is a schematic diagram after a pattern of a second conductive layer is formed in FIG. 10.

In an exemplary implementation, as shown in FIGS. 19 and 20, the pattern of the second conductive layer at least includes a gate electrode Gate22, a first electrode SD23 and a second electrode S24 of the second transistor, a gate electrode Gate32, a first electrode SD33 and a second electrode SD34 of the third transistor, a gate electrode SD42, a first electrode SD43 and a second electrode S44 of the fourth transistor, a gate electrode SD52, a first electrode SD53 and a second electrode S54 of the fifth transistor, a gate electrode SD62, a first electrode SD63 and a second electrode S64 of the sixth transistor, a gate electrode SD72, a first electrode SD73 and a second electrode S74 of the seventh transistor, a gate electrode SD82, a first electrode SD83 and a second electrode S84 of the eighth transistor, a gate electrode SD92, a first electrode SD93 and a second electrode S94 of the ninth transistor located in each shift register. In an exemplary implementation, any gate electrode of the gate electrode Gate22 of the second transistor to the gate electrode Gate82 of the eighth transistor has a shape of a strip and extends along the second direction D2.

In an exemplary implementation, the gate electrode Gate92 of the ninth transistor may have a shape of a bending line and may be in a “┘” shape.

In an exemplary implementation, a first electrode SD23 of the second transistor may be in a shape of a strip and extend at least partially along the second direction D2. The first electrode SD23 of the second transistor is connected with the first connection line through the first via, and is connected with the first region of the active pattern of the second transistor through the third via.

In an exemplary implementation, a second electrode SD24 of the second transistor may be in a “┐” shape. The second electrode SD24 of the second transistor is connected with the second connection line through the second via, and is connected with the second region of the active pattern of the second transistor through the fourth via.

In an exemplary implementation, a first electrode SD33 of the third transistor may be in a shape of a strip and extend at least partially along the second direction D2. The first electrode SD33 of the third transistor is connected with the first connection line through the first via, and is connected with the first region of the active pattern of the third transistor through the fifth via.

In an exemplary implementation, a second electrode SD34 of the third transistor may be in a “┐” shape. The second electrode SD34 of the third transistor is connected with the second connection line through the second via, and is connected with the second region of the active pattern of the third transistor through the sixth via.

In an exemplary implementation, a first electrode SD43 of the fourth transistor may have a shape of a strip and extend at least partially along the second direction D2. The first electrode SD43 of the fourth transistor is connected with the first connection line through the first via, and is connected with the first region of the active pattern of the fourth transistor through the seventh via.

In an exemplary implementation, a second electrode SD44 of the fourth transistor may be in a shape of a bending line. The second electrode SD44 of the fourth transistor includes a first electrode connection part SD441, a second electrode connection part SD442, and a third electrode connection part SD443, the first electrode connection part SD441 and the third electrode connection part SD443 extend along the second direction D2, the second electrode connection part SD442 extends along the first direction D1, the first electrode connection part SD441 and the third electrode connection part SD443 are located on opposite sides of the second electrode connection part SD442, the first electrode connection part SD441 is provided at a right angle to the second electrode connection part SD442, and the third electrode connection part SD443 is provided at a right angle to the second electrode connection part SD442. The second electrode SD44 of the fourth transistor is connected with the second connection line through the second via, and is connected with the second region of the active pattern of the fourth transistor through the eighth via.

In an exemplary implementation, a first electrode SD53 of the fifth transistor may have a shape of a strip and extend at least partially along the second direction D2. The first electrode SD53 of the fifth transistor is connected with the first connection line through the first via, and is connected with the first region of the active pattern of the fifth transistor through the ninth via.

In an exemplary implementation, a second electrode SD54 of the fifth transistor includes a fourth electrode connection part SD541, a fifth electrode connection part SD542, and a sixth electrode connection part SD543, the fourth electrode connection part SD541 and the sixth electrode connection part SD543 extend along the second direction D2, the fifth electrode connection part SD542 extends along the first direction D1, the fourth electrode connection part SD541 is located at a side of the fifth electrode connection part SD542 away from the display region, the sixth electrode connection part SD543 is located at a side of the fifth electrode connection part SD542 close to the display region, the fourth electrode connection part SD541 is provided at a right angle to the fifth electrode connection part SD542, and an end of the sixth electrode connection part SD543 is connected with the middle of the fifth electrode connection part SD542. The second electrode SD54 of the fifth transistor is connected with the second connection line through the second via, and is connected with the second region of the active pattern of the fifth transistor through the tenth via.

In an exemplary implementation, a first electrode SD63 of the sixth transistor may have a shape of a strip and extend at least partially along the second direction D2. The first electrode SD63 of the sixth transistor is connected with the first connection line through the first via, and is connected with the first region of the active pattern of the sixth transistor through the eleventh via.

In an exemplary implementation, a second electrode SD64 of the sixth transistor may be in a “┐” shape. The second electrode SD64 of the sixth transistor is connected with the second connection line through the second via, and is connected with the second region of the active pattern of the sixth transistor through the twelfth via.

In an exemplary implementation, a first electrode SD73 of the seventh transistor may have a shape of a strip and extend at least partially along the second direction D2. The first electrode SD73 of the seventh transistor is connected with the first connection line through the first via, and is connected with the first region of the active pattern of the seventh transistor through the thirteenth via.

In an exemplary implementation, a second electrode SD74 of the seventh transistor may be in a “┐” shape. The second electrode SD74 of the seventh transistor is connected with the second connection line through the second via, and is connected with the second region of the active pattern of the seventh transistor through the fourteenth via.

In an exemplary implementation, a first electrode SD83 of the eighth transistor may have a shape of a strip, and extends at least partially along the second direction D2. The first electrode SD83 of the eighth transistor is connected with the first connection line through the first via, and is connected with the first region of the active pattern of the eighth transistor through the fifteenth via.

In an exemplary implementation, a second electrode SD84 of the eighth transistor may be in a shape of a block and extend along the second direction D2. The second electrode SD84 of the eighth transistor is connected with the second connection line through the second via, and is connected with the second region of the active pattern of the eighth transistor through the sixteenth via.

In an exemplary implementation, a first electrode SD93 of the ninth transistor may be in a “┘” shape. The first electrode SD93 of the ninth transistor is connected with the first connection line through the first via, and is connected with the first region of the active pattern of the ninth transistor through the seventeenth via.

In an exemplary implementation, a second electrode SD94 of the ninth transistor may be in a shape of a block and extend along the second direction D2. The second electrode SD94 of the ninth transistor is connected with the second connection line through the second via, and is connected with the second region of the active pattern of the ninth transistor through the eighteenth via.
(5) A pattern of a planarization layer is formed. In an exemplary implementation, forming the pattern of the planarization layer may include depositing a third insulating thin film on the base substrate on which the above-mentioned patterns are formed, and coating a planarization thin film, patterning the third insulating thin film and the planarization thin film by a patterning process to form a pattern of a third insulating layer and the pattern of the planarization layer.

In an exemplary implementation, the semiconductor layer may be an amorphous silicon layer, a polycrystalline silicon layer, or may be a metal oxide layer. Herein, the metal oxide layer may use an oxide including indium and tin, an oxide including tungsten and indium, an oxide including tungsten, indium and zinc, an oxide including titanium and indium, an oxide including titanium, indium and tin, an oxide including indium and zinc, an oxide including silicon, indium and tin, or an oxide including indium or gallium and zinc. The metal oxide layer may be a single layer, a double-layer, or a multi-layer.

In an exemplary implementation, the first conductive layer and the second conductive layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo.

In an exemplary implementation, the first insulating layer, the second insulating layer, and the third insulating layer may be made of any one or more of Silicon Oxide (SiOx), Silicon Nitride (SiNx), and Silicon Oxynitride (SiON), and may be a single layer, a multi-layer, or a composite layer.

In an exemplary implementation, the planarization layer may be made of an organic material, such as resin.

In an exemplary implementation, after preparation of the drive structure layer is completed, a light emitting structure layer is prepared on the drive structure layer, and a preparation process of the light emitting structure layer may include following operations.

Depositing an anode conductive thin film on the base substrate on which the above-mentioned patterns are formed, patterning the anode conductive thin film using a patterning process to form a pattern of an anode conductive layer disposed on a second planarization layer, depositing a pixel definition film on the base substrate on which the aforementioned patterns are formed, patterning the pixel definition film by a patterning process to form a pixel definition layer pattern exposing the anode conductive layer pattern, coating an organic light emitting material on the base substrate on which the pixel definition layer pattern is formed, patterning the organic light emitting material by a patterning process to form an organic structure layer pattern, depositing a cathode conductive film on the base substrate on which the organic material layer pattern is formed, and patterning the cathode conductive film by a patterning process to form the cathode conductive layer.

So far, the light emitting structure layer has been manufactured on the base substrate.

In an exemplary implementation, the anode conductive layer includes at least a plurality of anode patterns. The plurality of anode patterns may include an anode of a first light emitting device, an anode of a second light emitting device, an anode of a third light emitting device, and an anode of a fourth light emitting device, wherein the anode of the first light emitting device is located at a red sub-pixel emitting red light, the anode of the second light emitting device may be located at a blue sub-pixel emitting blue light, the anode of the third light emitting device may be located at a first green sub-pixel emitting green light, and the anode of the fourth light emitting device may be located at a second green sub-pixel emitting green light.

In an exemplary implementation, the anode of the first light emitting device and the anode of the second light emitting device may be alternately disposed in the first direction, and the anode of the third light emitting device and the anode of the fourth light emitting device may be alternately disposed in the first direction. Alternatively, the anode of the first light emitting device and the anode of the second light emitting device may be alternately arranged in the second direction, and the anode of the third light emitting device and the anode of the fourth light emitting device may be alternately arranged in the second direction.

In an exemplary implementation, the anode conductive layer may be of a single-layer structure, such as Indium Tin Oxide (ITO) or Indium Zinc Oxide (IZO), or may be of a multi-layer composite structure, such as ITO/Ag/ITO.

In an exemplary implementation, the organic structure layer may at least include: an organic light emitting layer of the light emitting device.

In an exemplary implementation, the cathode conductive layer may include, at least, cathodes of a plurality of light emitting devices.

In an exemplary implementation, the cathode layer may be made of a metal material, such as any one or more of argentum (Ag), copper (Cu), aluminum (Al), and molybdenum (Mo), or a conductive alloy material of the above metals, such as an Aluminum Neodymium alloy (AlNd) or a Molybdenum Niobium alloy (MoNb), and may have a single-layer structure or a multi-layer composite structure, such as Mo/Cu/Mo. Exemplarily, the fourth conductive layer may be of a three-layer stacked structure formed of titanium, aluminum, and titanium.

In an exemplary implementation, the subsequent preparation process may include forming an encapsulation structure layer on the cathode conductive layer, and the encapsulation structure layer may include a first encapsulation layer, a second encapsulation layer and a third encapsulation layer which are stacked. The first encapsulation layer and the third encapsulation layer may be made of an inorganic material, the second encapsulation layer may be made of an organic material, and the second encapsulation layer is arranged between the first encapsulation layer and the third encapsulation layer to ensure that external water vapor cannot enter the light emitting structure layer.

The display substrate according to the embodiment of the present disclosure may be applied to a display product with any resolution.

An embodiment of the present disclosure further provides a display apparatus, which may include: a display substrate.

The display substrate is the display substrate according to any of the aforementioned embodiments, and has similar implementation principles and implementation effects, which will not be repeated here.

In an exemplary implementation, the display apparatus may be any product or component with a display function such as a wearable device, a mobile phone, a tablet computer, a television, a display, a laptop computer, a digital photo frame, and a navigator.

The drawings of the embodiments of the present disclosure only involve structures involved in the embodiments of the present disclosure, and other structures may refer to a general design.

For the sake of clarity, a thickness and size of a layer or a micro structure are enlarged in the accompanying drawings used for describing the embodiments of the present disclosure. It may be understood that when an element such as a layer, film, region, or substrate is described as being “on” or “under” another element, the element may be “directly” located “on” or “under” the another element, or there may be an intermediate element.

Although the implementations of the present disclosure are disclosed above, the contents are only implementations used for ease of understanding of the present disclosure, but not intended to limit the present disclosure. Any of those skilled in the art of the present disclosure can make any modifications and variations in the implementation mode and details without departing from the spirit and scope of the present disclosure. However, the protection scope of the present disclosure should be subject to the scope defined by the appended claims.

1. A display substrate, having a display region and a non-display region provided on and surrounding at least one side of the display region, wherein the display region is provided with pixel drive circuits arranged in an array, and the non-display region is provided with a gate drive circuit and a gating signal line group, the gating signal line group comprises: a plurality of gating signal lines, and the gate drive circuit is electrically connected with the pixel drive circuits and the gating signal line group respectively;
a gating signal line extends along a first direction, the plurality of gating signal lines are arranged along a second direction, and the first direction and the second direction intersect;
the gate drive circuit comprises a plurality of shift registers, a shift register comprises: a gating sub-circuit, wherein the gating sub-circuit is electrically connected with a portion of the gating signal lines in the gating signal line group, the gating sub-circuit comprises a plurality of gating transistors, for any shift register, the plurality of gating transistors in the gating sub-circuit are arranged along the first direction.

2. The display substrate according to claim 1, wherein the shift register comprises M gating signal terminals, and the gating signal line group comprises 2M gating signal lines;
a m-th gating signal terminal is electrically connected with a (2m-1)-th gating signal line or a 2m-th gating signal line, and a signal of the (2m-1)-th gating signal line and a signal of the 2m-th gating signal line are mutually inverted signals, 1≤m≤M.

3. The display substrate according to claim 1, wherein the non-display region has a signal line region and a device region, the gate drive circuit is at least partially located in the device region, the signal line region comprises a first signal line region, a second signal line region and a third signal line region sequentially disposed along a direction close to the display region, and the device region comprises a first device region, a second device region, a third device region and a fourth device region sequentially disposed along the direction close to the display region;
the first signal line region is located at a side of the first device region away from the display region, and the third signal line region is located at a side of the fourth device region close to the display region;
the gating signal line group is located in the first signal line region, and the gating sub-circuit is located in the first device region.

4. The display substrate according to claim 3, wherein the second signal line region is located between the first signal line region and the first device region, or between the first device region and the second device region.

5. The display substrate according to claim 3, wherein a length of the first signal line region along the second direction is greater than a length of the second signal line region along the second direction, and a length of the third signal line region along the second direction is greater than the length of the second signal line region along the second direction.

6. The display substrate according to claim 3, wherein the non-display region is further provided with a clock signal line group, and the gate drive circuit is electrically connected with the clock signal line group;
the clock signal line group is located in the first signal line region, and is located at a side of the gating signal line group away from the display region.

7. The display substrate according to claim 3, wherein the clock signal line group comprises a control clock signal line group and an output clock signal line group;
the control clock signal line group comprises a plurality of control clock signal lines, a control clock signal line extends along the first direction, the plurality of control clock signal lines are arranged along the second direction, the output clock signal line group comprises a plurality of output clock signal lines, an output clock signal line extends along the first direction, the plurality of output clock signal lines are arranged along the second direction, a line width of the output clock signal line is greater than a line width of the control clock signal line and a line width of the gating signal line;
the shift register comprises a plurality of control clock terminals and a plurality of output clock terminals, any one of the plurality of control clock terminals is electrically connected with one of the control clock signal lines in the control clock signal line group, and any one of the plurality of output clock terminals is electrically connected with one of the output clock signal lines in the output clock signal line group;
for any shift register, the plurality of control clock terminals are electrically connected with a portion of signal lines in the control clock signal line group, and the plurality of output clock terminals are electrically connected with a portion of the signal lines in the output clock signal line group;
the output clock signal line group is located at a side of the control clock signal line group away from the display region.

8. The display substrate according to claim 3, wherein the non-display region is further provided with a first high-level power supply line and a second high-level power supply line;
the shift register comprises: a first high-level power supply terminal and a second high-level power supply terminal; for any shift register, the first high-level power supply terminal is electrically connected with the first high-level power supply line, and the second high-level power supply terminal is electrically connected with the second high-level power supply line;
the first high-level power supply line and the second high-level power supply line are located in the second signal line region;
a line width of any one of the first high-level power supply line and the second high-level power supply line is greater than a line width of any signal line located in the first signal line region.

9. The display substrate according to claim 3, wherein the non-display region is further provided with a first low-level power supply line and a second low-level power supply line;
the shift register comprises: a first low-level power supply terminal and a second low-level power supply terminal; for any shift register, the first low-level power supply terminal is electrically connected with the first low-level power supply line, and the second low-level power supply terminal is electrically connected with the second low-level power supply line;
the first low-level power supply line and the second low-level power supply line are located in the third signal line region, and the first low-level power supply line is located at a side of the second low-level power supply line away from the display region;
a line width of any one of the first low-level power supply line and the second low-level power supply line is greater than a line width of any signal line located in the first signal line region, and a line width of the first low-level power supply line is less than a line width of the second low-level power supply line.

10. The display substrate according to claim 3, wherein a length of the second device region along the second direction is greater than a length of the first device region along the second direction, a length of the third device region along the second direction is greater than the length of the second device region along the second direction, and a length of the fourth device region along the second direction is greater than the length of the third device region along the second direction.

11. The display substrate according to claim 3, wherein the shift register further comprises an input sub-circuit, a node setting sub-circuit, and a preprocessing sub-circuit; the plurality of control clock terminals comprise: a first control clock terminal to a third control clock terminal;
the node setting sub-circuit is electrically connected at least with a second high-level power supply terminal, a second low-level power supply terminal, a second control clock terminal, a third control clock terminal, a first node and a third node, respectively, and is configured to provide a signal of the second high-level power supply terminal or the second low-level power supply terminal to the first node under control of signals of the second control clock terminal, the third control clock terminal and the third node;
the input sub-circuit is at least electrically connected with the third control clock terminal, the third node and a fifth node, respectively, and is configured to provide a signal of the third control clock terminal to the fifth node under control of signals of the third node and the third control clock terminal;
the preprocessing sub-circuit is at least electrically connected with a second node, the third node, a fourth node, a first high-level power supply terminal and the first control clock terminal, respectively, and is configured to provide a signal of the first control clock terminal to the fourth node and provide a signal of the fourth node to the first high-level power supply terminal under control of a signal of the second node;
the gating sub-circuit is further electrically connected with the second control clock terminal and the second node, respectively, and is configured to provide a signal of the second control clock terminal to the second node under control of signals of a plurality of gating signal terminals; and
the input sub-circuit, the node setting sub-circuit and the preprocessing sub-circuit are located in the second device region and arranged along the first direction, and the preprocessing sub-circuit is located between the input sub-circuit and the node setting sub-circuit.

12. The display substrate according to claim 11, wherein the preprocessing sub-circuit comprises a plurality of preprocessing transistors and a preprocessing capacitor;
the preprocessing capacitor is located at a side of the plurality of preprocessing transistors close to the node setting sub-circuit.

13. The display substrate according to claim 3, wherein the shift register further comprises a node separation sub-circuit;
the node separation sub-circuit is electrically connected with a third control clock terminal, a first high-level power supply terminal, a second low-level power supply terminal, a first node, a fifth node, a sixth node, a seventh node, an eighth node, and a ninth node, respectively, and is configured to provide a signal of the fifth node to the sixth node to the ninth node respectively under control of signals of the third control clock terminal and the first node, or to provide a signal of the first high-level power supply terminal to the fifth node under control of a signal of the sixth node; and
the node separation sub-circuit is located in the third device region.

14. The display substrate according to claim 3, wherein the shift register further comprises an output sub-circuit;
the output sub-circuit is at least electrically connected with a plurality of output clock terminals, a first low-level power supply terminal and a plurality of signal output terminals, respectively, and is configured to output a signal of a corresponding output clock terminal or the first low-level power supply terminal to the plurality of signal output terminals; and
the output sub-circuit is located in the fourth device region;
wherein the output sub-circuit further comprises a plurality of output capacitors arranged in an array along the first direction and the second direction.

15. (canceled)

16. The display substrate according to claim 3, wherein the shift register further comprises a reset sub-circuit and a noise reduction sub-circuit, and the plurality of control clock terminals comprises: a first control clock terminal to a third control clock terminal;
the reset sub-circuit is at least electrically connected with a global reset signal terminal, a third node, a fourth node, a first high-level power supply terminal and a second low-level power supply terminal, respectively, and is configured to provide an electrical connection from the second low-level power supply terminal to the third node, the fourth node and the first high-level power supply terminal under control of a signal of the global reset signal terminal;
the noise reduction sub-circuit is electrically connected at least with a first node, a second node, a ninth node, the first control clock terminal, the second control clock terminal and the second low-level power supply terminal, respectively, and is configured to provide a signal of the second control clock terminal to the second node under control of a signal of the first control clock terminal, and provide a signal of the second low-level power supply terminal to the first node under control of a signal of the ninth node; and
the reset sub-circuit and the noise reduction sub-circuit are located in the second device region, and the reset sub-circuit and the preprocessing sub-circuit are arranged along the second direction.

17. The display substrate according to claim 16, wherein the non-display region is further provided with a reset signal line;
a global reset signal terminal of the shift register is electrically connected with the reset signal line, and the reset signal line is located in the first signal line region.

18. The display substrate according to claim 3, wherein the gate drive circuit comprises: a plurality of shift register groups, a shift register group comprises N1 shift register units, and a shift register unit comprises N2 shift registers, N1, N2≥2;
a portion of gating signal lines connected with a plurality of gating signal terminals of a shift register are called gating signal line units; gating signal lines comprised in gating signal line units connected with any two shift registers located in a same shift register unit are the same, and at least one of gating signal lines comprised in gating signal line units connected with any two shift register units located in a same shift register group is different; and gating signal lines comprised in gating signal line units connected with n1-th shift register units located in different shift register groups are the same, 1≤n1≤N1.

19. The display substrate according to claim 18, wherein a portion of control clock signal lines connected with a plurality of control clock terminals of a shift register are called control clock signal line units, and a portion of output clock signal lines connected with a plurality of output clock terminals of a shift register are called output clock signal line units;
at least one of control clock signal lines comprised in control clock signal line units connected with any two shift registers located in a same shift register unit are different, and at least one of output clock signal lines comprised in output clock signal line units connected with any two shift registers located in a same shift register unit are different; control clock signal lines comprised in control clock signal line units connected with n2-th shift registers located in different shift register units are the same, and output clock signal lines comprised in output clock signal line units connected with n2-th shift registers located in different shift register units are the same, 1≤n2≤N2.

20. The display substrate according to claim 1, comprising a base substrate and a drive structure layer disposed on the base substrate, wherein the shift register comprises a plurality of transistors;
the drive structure layer comprises a first conductive layer, a first insulating layer, a semiconductor layer, a second insulating layer and a second conductive layer which are stacked on the base substrate;
the semiconductor layer at least comprises: active patterns of a plurality of transistors in the shift register; and
the second conductive layer at least comprises gate electrodes, first electrodes, and second electrodes of the plurality of transistors in the shift register;
wherein the display substrate further comprises a gating signal line, a control clock signal line, an output clock signal line, a first high-level power supply line, a second high-level power supply line, a first low-level power supply line, and a second low-level power supply line, wherein any signal line of the gating signal line, the control clock signal line, the output clock signal line, the first high-level power supply line, the second high-level power supply line, the first low-level power supply line, and the second low-level power supply line is of a single-layer structure and located in the first conductive layer, or of a double-layer structure and located in the first conductive layer and the second conductive layer;
wherein the non-display region is further provided with a first connection line and a second connection line, and the first connection line and the second connection line are located in the first conductive layer;
first electrodes of all gating transistors located in a same gating sub-circuit are electrically connected with the first connection line, and second electrodes of a plurality of gating transistors located in a same gating sub-circuit are electrically connected with the second connection line; and
any electrode of a gate electrode, a first electrode and a second electrode in any gating transistor extends at least partially along the second direction, and the first connection line and the second connection line extend along the first direction.

21-30. (canceled)

31. A display apparatus, comprising: the display substrate according to claim 1.
